(19) United States
(12) Patent Application Publication
(10) Pub. No.: US 2024/0320475 A1
(43) Pub. Date: Sep. 26, 2024

(54) SYSTEMS AND METHODS FOR DATA PROCESSING USING MACHINE LEARNING

(71) Applicant: ADOBE INC., SAN JOSE, CA (US)

(72) Inventors: Rebecca Dorothy West, Auburn, CA (US); Lauren Dest, Austin, TX (US); Mihir Naware, Redwood City, CA (US); Elliot Axel Patrick Puzenat, Le Plessis Robinson (FR); Stephen Becigneul, Levallois-Perret (FR); Alexis Tessier, Eckwersheim (FR); Suman Basetty, Fremont, CA (US); Kimberly K. Lenox, Orinda, CA (US); Anil Kamath, Los Altos HIlls, CA (US)

(21) Appl. No.: 18/477,650

(22) Filed: Sep. 29, 2023

Related U.S. Application Data
(60) Provisional application No. 63/491,499, filed on Mar. 21, 2023.

(51) Int. Cl. G06N 3/0455

(52) U.S. Cl. CPC G06N 3/0455; G06F 40/186

(57) ABSTRACT

A method, non-transitory computer readable medium, apparatus, and system for data processing are described. An embodiment of the present disclosure includes receiving, from a content provider via a user interface, a query about a chart that includes information related to a domain. A machine learning model generates a response to the query based on the chart and a corpus of documents in the domain. The response includes information from the corpus of documents. The user interface provides at least a portion of the response to the content provider.

### CROSS-REFERENCE TO RELATED APPLICATION

This application claims the benefit, under 35 U.S.C. § 119, of the filing date of U.S. Provisional Application No. 63/491,499, filed on Mar. 21, 2023, in the United States Patent and Trademark Office. The disclosure of U.S. Provisional Application No. 63/491,499 is incorporated by reference herein in its entirety.

### BACKGROUND

The following relates generally to data processing, and more specifically to data processing using machine learning. Data processing refers to a collection and manipulation of data to produce meaningful information. Machine learning is an information processing field in which algorithms or models such as artificial neural networks are trained to make predictive outputs in response to input data without being specifically programmed to do so.

In some cases, a set of data is analyzed to identify an important trend or point of interest in the data, and the trend or point of interest is used to inform a content provider action. However, a process of accurately describing the trend or point of interest and identifying appropriate content provider actions in light of the trend or point of interest is both time-intensive and labor-intensive. There is therefore a need in the art for a data processing system that identifies a content provider opportunity in an efficient manner.

### SUMMARY

Embodiments of the present disclosure provide a data processing system that generates a response to a content provider query about a chart that includes information related to a domain. In some cases, the data processing system generates the response using a machine learning model based on the chart and a corpus of documents in the domain, such that the response includes information from the corpus of documents.

In some cases, by generating the response using the machine learning model, the data processing system is able to provide the response using less time and resources than a response based on a manual analysis of the query and the corpus of documents would require. Furthermore, in some cases, because the machine learning model generates the response based on the chart, the data processing system is able to provide a response based on a chart modality, unlike conventional data processing systems that use machine learning. Because the machine learning model is able to generate the response based on the chart, the machine learning model is able to generate a response using information that might only be represented in the chart.

A method, apparatus, non-transitory computer readable medium, and system for data processing are described. One or more aspects of the method, apparatus, non-transitory computer readable medium, and system include receiving, from a content provider via a user interface, a query about a chart that includes information related to a domain; generating a response to the query based on the chart and a corpus of documents in the domain, wherein the response includes information from the corpus of documents; and providing at least a portion of the response to the content provider.

A method, apparatus, non-transitory computer readable medium, and system for data processing are described. One or more aspects of the method, apparatus, non-transitory computer readable medium, and system include obtaining training data including a corpus of documents from a domain, chart data from the domain, a training query, and a ground-truth response to the training query and training a machine learning model to answer domain-specific questions in the domain using the training data.

A system and an apparatus for data processing are described. One or more aspects of the system and the apparatus include at least one processor; at least one memory storing instructions executable by the at least one processor; a user interface configured to receive a query about a chart that includes information related to a domain; and a machine learning model including machine learning parameters stored in the at least one memory and trained to generate a response to the query based on the chart and a corpus of documents in the domain, wherein the response includes information from the corpus of documents.

### BRIEF DESCRIPTION OF THE DRAWINGS

FIG. 1 shows an example of a data processing system according to aspects of the present disclosure.

FIG. 2 shows an example of a data processing apparatus according to aspects of the present disclosure.

FIG. 3 shows an example of a transformer according to aspects of the present disclosure.

FIG. 4 shows an example of data flow in a data processing system according to aspects of the present disclosure.

FIG. 5 shows an example of a method for generating an insight and an opportunity according to aspects of the present disclosure.

FIG. 6 shows an example of a method for responding to a query according to aspects of the present disclosure.

FIG. 7 shows an example of a method for generating an initial response according to aspects of the present disclosure.

FIG. 8 shows an example of initial responses according to aspects of the present disclosure.

FIG. 9 shows an example of portions of an initial response according to aspects of the present disclosure.

FIG. 10 shows an example of a user interface message according to aspects of the present disclosure.

FIG. 11 shows an example of a response according to aspects of the present disclosure.

FIG. 12 shows an example of an insight generated based on a campaign according to aspects of the present disclosure.

FIG. 13 shows an example of an additional visual element according to aspects of the present disclosure.

FIG. 14 shows an example of a method for training a machine learning model according to aspects of the present disclosure.

### DETAILED DESCRIPTION

In some cases, a set of data is analyzed to identify an important trend or point of interest in the data, and the trend or point of interest is used to inform a content provider action. For example, in some cases, content distribution and user experience strategies are informed by a wide variety of factors, including ever-changing market trends, user preferences, and signals from social, economic, and political landscapes. An ability to quickly and intelligently understand, plan for, and react to such factors greatly assists a content provider in achieving its goals.

Furthermore, users are increasingly embracing digital channels to engage with content providers and are demanding that content providers personalize their interactions. Therefore, both users and content providers benefit when an intent, stage, and context of users are understood and a digital experience is tailored for the users. A confluence of personalization at scale along with a myriad of macro influences presents an opportunity for a data processing system for digital user experience management that operates at a granularity of an individual user's journey and sequence of experiences, all while helping a content provider to achieve its goals.

However, producing an effective content distribution campaign by synthesizing external and internal data into actionable opportunities, creating superior campaign components (e.g., content, journeys, objectives, etc.), and optimizing a content distribution strategy over time is not easily achievable for a content provider team, and added challenges of a demand from content providers for new, fresh, and personalized user experiences and siloed teams balancing various overlapping efforts creates further complication for creating an effective campaign.

For example, in some cases, a superior campaign draws upon vast and disparate external and internal data that individual strategists and analysts are not able to effectively comprehend or synthesize within an allotted time. In some cases, a significant part of an analyst's time is spent on retrieving basic key performance indicator (KPI) questions with little bandwidth for deep analysis, while in some cases, strategists such as campaign owners and managers rely on an ad hoc analysis of internal and external sources from analysts to come to a point solution campaign.

Furthermore, in some cases, a process of conceiving, executing, and evaluating a campaign is laborious and time-consuming and is constrained both by a number of available team members and an ability to rapidly and effectively respond to quickly moving user preferences. Additionally, in some cases, an end-to-end content distribution effort is scattered across different roles, making an ability to quickly and dynamically adjust campaign components based on ever-changing trends a challenge.

For example, in some cases, strategists rely on operations teams, creative teams, and other team members to execute a point solution campaign. During such a process, in some cases, a performance-based adjustment to the campaign is time-consuming, as the adjustment demands waiting for a full cycle to re-engage team members that are now occupied with different tasks. Additionally, in some cases, a content distribution effort is hampered by a lack of healthy knowledge-sharing practices across teams, resulting in silos, inefficiencies, and bottlenecks.

Still further, in some cases, content distribution workflows are heavy, manual, and dependent upon a constant supply of human ingenuity and accuracy. For example, in some cases, operations team members that are focused on building user journeys perform numerous iterations according to an intuition of what aspects of a prospective user journey might be effective. Additionally, in some cases, creative team members have a limited capacity to create variations of content for campaigns, particularly based on historical performance and content affinity variations for clients and consumers.

Additionally, in some cases, an ability to create a tailored experience and user journey for each unique user is constrained by an ability of content provider teams to generate and deliver appropriate content at an appropriate time.

According to some aspects, a data processing system including a user interface and a machine learning model is provided. In some cases, the user interface is configured to receive a query about a chart that includes information related to a domain. In some aspects, the machine learning model is configured and/or trained to generate a response to the query based on the chart and a corpus of documents in the domain. In some aspects, the response includes information from the corpus of documents.

By generating a response to the query using the machine learning model, the data processing system is able to provide an insight and/or an opportunity relating to the domain in a less laborious and time-consuming manner than a conventional analysis performed by an analyst. Furthermore, in some aspects, by generating the response based on the chart using the machine learning model, the data processing system is able to provide an insight and/or opportunity based on visual information provided in the chart.

Accordingly, unlike conventional data processing systems that employ a machine learning model, in some aspects, the data processing system goes beyond internal workflow and knowledge management to deliver insights and opportunities to a content provider. According to some aspects, the data processing system includes a comprehensive user experience management suite (e.g., a user experience platform) for planning, execution, and analysis to execute personalization-at-scale strategies.

According to some aspects, the data processing system streamlines and enhances an end-to-end content distribution campaign, from planning to ideation and execution, through monitoring and optimization via machine learning. In an example, in some cases, the machine learning model generates an insight and/or an opportunity based on external data, user historical data, and capabilities of the user experience platform. In some cases, the synthesis and summarizing skills of the machine learning model are employed to proactively alert a content provider of an insight and/or an opportunity that align with objectives of the content provider.

A data processing system according to an aspect of the present disclosure is used in a data analysis context. In an example, a user experience platform of the data processing system identifies a trend in data that the user experience platform monitors for a content provider (such as data relating to a relevant domain for the content provider, e.g., demographic data for travelers). In some cases, the user experience platform provides information and a visual element (such as a chart) relating to the identified data trend (e.g., a relative increase in users who travel by themselves compared to other demographic groups of travelers) to the content provider. In some cases, the content provider queries the data processing apparatus to generate an insight relating to the data trend. The data processing apparatus generates a response (e.g., an insight) to the query using a machine learning model. In some cases, the data processing apparatus generates the insight automatically in response to the identification of the data trend.

In some cases, the user experience platform generates a prompt for the machine learning model based on the data trend. In some cases, the prompt includes information related to a domain (such as the domain of relevance to the content provider), as well as an instruction to generate an insight relating to the data trend based on the information included in the prompt.

In some cases, the data processing apparatus generates the insight based on the chart. For example, in some cases, the data processing apparatus encodes the chart using a multimodal encoder so that the machine learning model processes the information that is depicted in the chart.

In some cases, the insight includes a natural language description of the data trend. In some cases, the insight includes a natural language analysis of the data trend (such as an identification of a predicted cause or contributing factor for the data trend and a prediction of an effect of the data trend). In some cases, the insight includes a text instruction provided in an appropriate format (such as an instruction, code, a macro, etc.) for a different component (such as the user experience platform) to take some action (such as retrieve, generate, and or/display content).

In some cases, the data processing apparatus displays the insight or a portion of the insight to the content provider via the user interface. In some cases, the at least the portion of the insight is displayed with a visual element (such as a chart) corresponding to the insight and/or the data trend.

In some cases, the content provider provides a query about the insight. In some cases, the query includes a query about the visual element (such as the chart) displayed by the user interface. In some cases, the query comprises natural language. In some cases, the query comprises a content provider selection of a graphical element displayed by the user interface.

In some cases, the data processing apparatus generates a response (e.g., an opportunity) to the query using the machine learning model. In some cases, the user experience platform generates a prompt for the machine learning model based on the insight. In some cases, the prompt includes information related to the domain (such as the domain of relevance to the content provider), as well as an instruction to generate an opportunity relating to the insight based on the information included in the prompt. In some cases, the data processing apparatus generates the opportunity based on the chart. For example, in some cases, the data processing apparatus encodes the chart using the multimodal encoder so that the machine learning model processes the information that is depicted in the chart.

In some cases, the opportunity includes a natural language description of an action for the content provider to take based on the insight. In some cases, the opportunity includes a natural language suggestion to the content provider to instruct the data processing system to take a further action (such as identifying a group of content providers, generating a content distribution campaign, etc.) based on the insight. In some cases, the opportunity includes a text instruction provided in an appropriate format (such as an instruction, code, a macro, etc.) for a different component (such as the user experience platform) to take an action (such as identifying the group of content providers, generating the content distribution campaign, etc.).

In some cases, the data processing apparatus displays the opportunity or a portion of the opportunity to the content provider via the user interface. In some cases, the at least the portion of the opportunity is displayed with a visual element (such as a chart) corresponding to the opportunity.

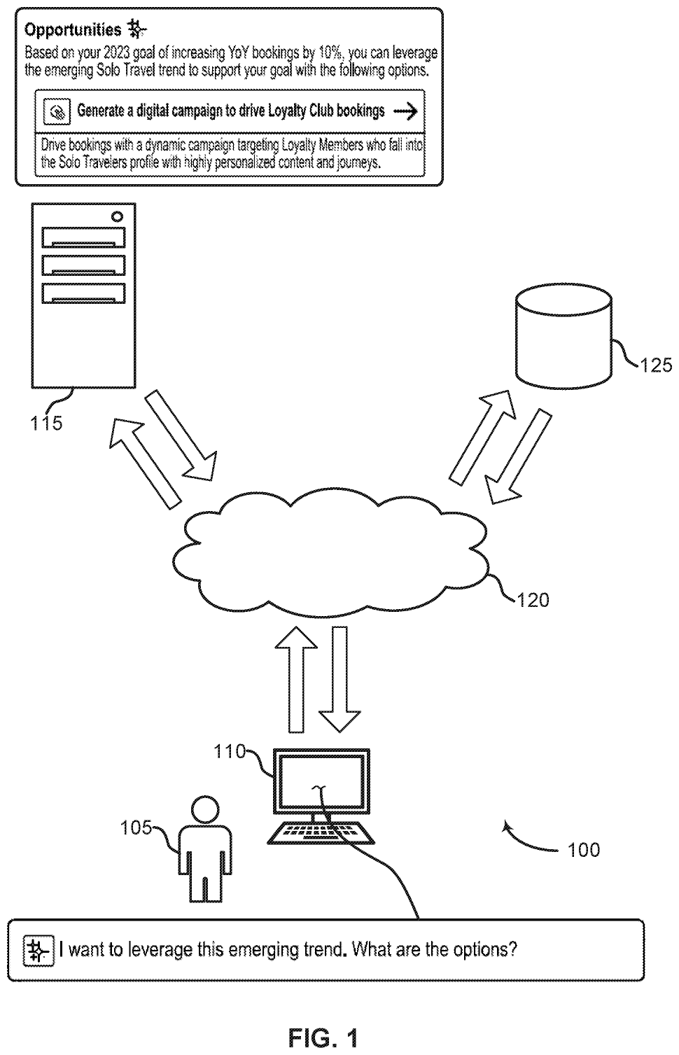

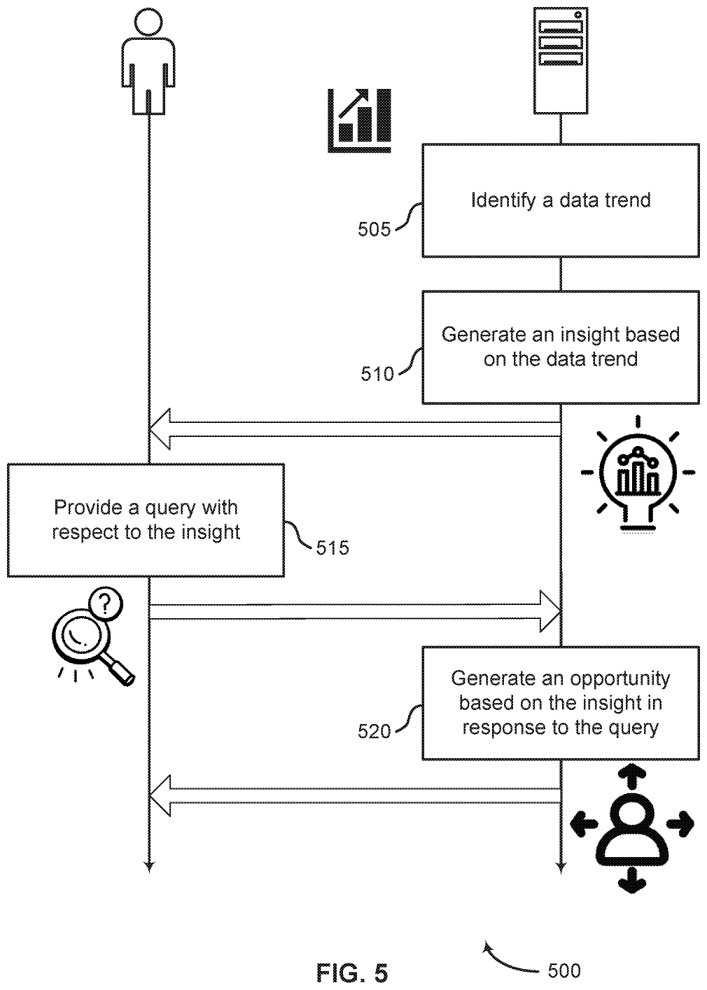

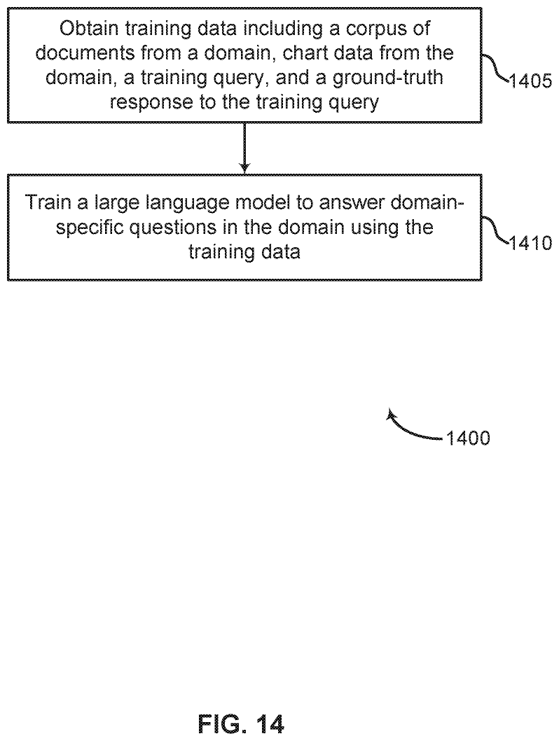

Further example applications of the present disclosure in the data analysis context are provided with reference to FIGS. 1 and 5. Details regarding the architecture of the data processing system are provided with reference to FIGS. 1-4. Details regarding a process for data processing are provided with reference to FIGS. 5-13. Details regarding a process for training a machine learning model are provided with reference to FIG. 14.

As used herein, a “query” refers to an input from a content provider provided to a user interface. In some cases, the query comprises text (such as natural language sentences) entered into the user interface by the content provider. As used herein, “natural language” refers to any language that has emerged through natural use. In some cases, the query comprises a selection of an element (such as text) displayed by the user interface.

As used herein, in some cases, a “content provider” refers to a person or entity that interacts with the data processing system and/or data processing apparatus. As used herein, “content” refers to any form of media, including goods, services, physically tangible media, and the like, and digital content, including media such as text, audio, images, video, or a combination thereof. As used herein, a “communication channel” or a “content distribution channel” refers to a physical channel (such as a mailing service, a physical location such as a store, a hotel, an amusement park, etc., and the like) or a digital channel (such as a website, a software application, an Internet-based application, an email service, a messaging service such as SMS, instant messaging, etc., a television service, a telephone service, etc.) through which content or digital content is provided. As used herein, “customized content” refers to content that is customized according to data associated with a content provider or a user.

As used herein, a “chart” refers to a visual element (such as an image) that includes a visual representation (such as a description or summarization) of information included in a dataset. As used herein, “chart data” refers to one or more of data represented in a chart and data used for creating the chart.

As used herein, a “domain” refers to a category of information related to a corpus of documents or data. Examples of a domain include a specific technology area, a business market, a geographical region, an area of study, etc. As used herein, a “corpus of documents” refers to a set of documents. As used herein, a “document” refers to a discrete set or grouping of related information or data. In some cases, a document is implemented as a computer file. In some cases, a document includes text, an image (such as a chart), a video, audio, etc.

As used herein, a “response” refers to an output of the machine learning model. In some cases, the response comprises text. In some cases, the text comprises natural language text. In some cases, the machine learning model is trained to generate the response. In some cases, the response is generated based on a prompt. As used herein, a “prompt” refers to an input to the machine learning model. In some cases, the prompt includes a natural language input. In some cases, the prompt includes one or more embeddings.

As used herein, an “embedding” refers to a mathematical representation of an object (such as text, an image, a chart, audio, etc.) in a lower-dimensional space, such that information about the object is more easily captured and analyzed by a machine learning model. For example, in some cases, an embedding is a numerical representation of the object in a continuous vector space in which objects that have similar semantic information correspond to vectors that are numerically similar to and thus “closer” to each other, providing for an ability of a machine learning model to effectively compare the objects corresponding to the embeddings with each other.

In some cases, an embedding is produced in a “modality” (such as a text modality, a chart modality, an image modality, an audio modality, etc.) that corresponds to a modality of the corresponding object. In some cases, embeddings in different modalities include different dimensions and characteristics, which makes a direct comparison of embeddings from different modalities difficult. In some cases, an embedding for an object is generated or translated into a multimodal embedding space, such that objects from multiple modalities are effectively comparable with each other.

As used herein, a “chart embedding” refers to an embedding of a chart that includes a numerical representation of information depicted by the chart. For example, in some cases, a chart embedding of a pie chart includes information depicted by labels of the pie chart, relative proportions of the area of the pie corresponding to the labels, or a combination thereof; a chart embedding of a bar chart includes information depicted by labels of the bar chart, axes of the pie chart, relative lengths of the bars, or a combination thereof, a chart embedding of a point chart includes information depicted by labels of the point chart, axes of the point chart, positions of points of the point chart relative to axes of the point chart; etc.

As used herein, in some cases, an “insight” refers to an output of the machine learning model relating to a data trend. For example, in some cases, an insight includes an analysis of the data trend that is based on information available to the machine learning model, either via training or via being provided to the machine learning model as a prompt or a portion of a prompt.

As used herein, in some cases, an “opportunity” refers to an output of the machine learning model relating to an action or occurrence to be taken in response to an insight. For example, in some cases, an opportunity includes a suggestion in natural language of an action to be performed given an insight that has been identified. In some cases, an insight or data relating to an insight are included as a prompt for the machine learning model to generate an opportunity. In some cases, a “response” includes an insight, an opportunity, or a combination thereof.

As used herein, in some cases, a “user experience platform” includes a set of creative, analytics, social, advertising, media optimization, targeting, Web experience management, journey orchestration and content management tools. In some cases, the user experience platform communicates with a database. In some cases, the user experience platform comprises the database.

Accordingly, in some cases, by generating the response using the machine learning model, the data processing system is able to provide the response using less time and resources than a response based on a manual analysis of the query and the corpus of documents would require. Furthermore, in some cases, because the machine learning model generates the response based on the chart, the data processing system is able to provide a response based on a chart modality, unlike conventional data processing systems that use machine learning. Because the machine learning model is able to generate the response based on the chart, the machine learning model is able to generate a response using information that might only be represented in the chart.

Furthermore, unlike conventional data processing systems which use employ generative machine learning, according to some aspects, the data processing system goes beyond image and text generation to deliver insights and opportunities to a content provider to create a content distribution package in addition to text and image content, such as harmonious multimodal experiences and performant content that leverages content insights from user's data and content. According to some aspects, the data processing system includes a comprehensive user experience management suite for planning, execution, and analysis to execute personalization-at-scale strategies. According to some aspects, the data processing system integrates workflows for experience creation and delivery so that there is no need for a content provider to employ another system.

According to some aspects, the data processing system assists with an ideation, definition, expansion, and refinement of an audience for the content distribution campaign. For example, in some cases, the machine learning model qualifies and quantifies the audience using summary statistics and described traits of the audience along with projected performance of the audience towards the content distribution objective of the content provider.

According to some aspects, the data processing system employs at least one of the user experience platform and the machine learning model to generate a complete content distribution campaign, including a program, messaging, content, and journey, or a combination thereof. For example, in some cases, the data processing system optimizes the content distribution campaign for a target audience to meet the content distribution objective of the content provider.

According to some aspects, the data processing system infuses capabilities of the machine learning model with capabilities of the user experience cloud to provide a multi-modal conversational interface capable of brainstorming, ideation, and reasoning, that retains and adapts to context. In some cases, the conversational interface is implemented as a copilot for user experience management.

According to some aspects, the data processing system is directed by additional inputs and/or dimensions to dynamically and continuously regenerate generated outputs. According to some aspects, journeys, journey simulation, and performance predictions are based on historical journey data of a content provider combined with external journey data leveraged by the machine learning model.

Accordingly, in some cases, the data processing system provides a content provider with efficiency, efficacy, scale, agility, velocity, ideation, collaboration, and/or execution, thereby allowing the content provider to do more with less.

### Data Processing System

A system and an apparatus for data processing are described with reference to FIGS. 1-4. One or more aspects of the system and the apparatus include at least one processor; at least one memory storing instructions executable by the at least one processor; a user interface configured to receive a query about a chart that includes information related to a domain; and a machine learning model including machine learning parameters stored in the at least one memory and trained to generate a response to the query based on the chart and a corpus of documents in the domain, wherein the response includes information from the corpus of documents. In some aspects, the machine learning model comprises a large language model. In some aspects, the machine learning model comprises a transformer.

Some examples of the system and the apparatus further include a multimodal encoder including multimodal encoder parameters stored in the at least one memory and trained to encode the chart to obtain a chart embedding. Some examples of the apparatus further include a user experience platform configured to generate a prompt for the machine learning model.

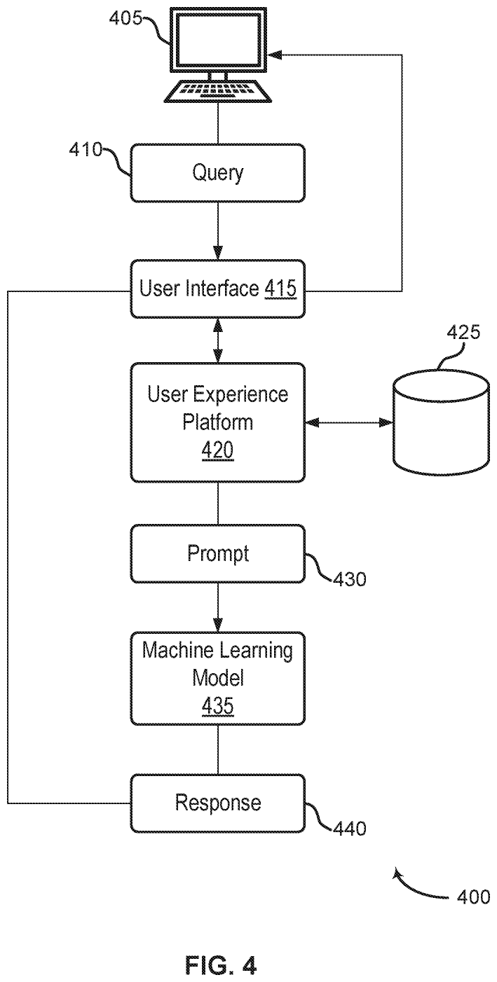

FIG. 1 shows an example of a data processing system 100 according to aspects of the present disclosure. The example shown includes content provider 105, content provider device 110, data processing apparatus 115, cloud 120, and database 125. Data processing system 100 is an example of, or includes aspects of, the corresponding element described with reference to FIG. 4.

Referring to FIG. 1, content provider 105 provides a query (e.g., “I want to leverage this emerging trend. What are the options?”) to data processing apparatus 115 via a user interface provided on content provider device 110 by data processing apparatus 115. In the example of FIG. 1, the query refers to information relating to a data trend displayed on the user interface by data processing apparatus 115. In some cases, the information includes a chart. In some cases, the query refers to an initial response (for example, an insight) displayed by data processing apparatus 115.

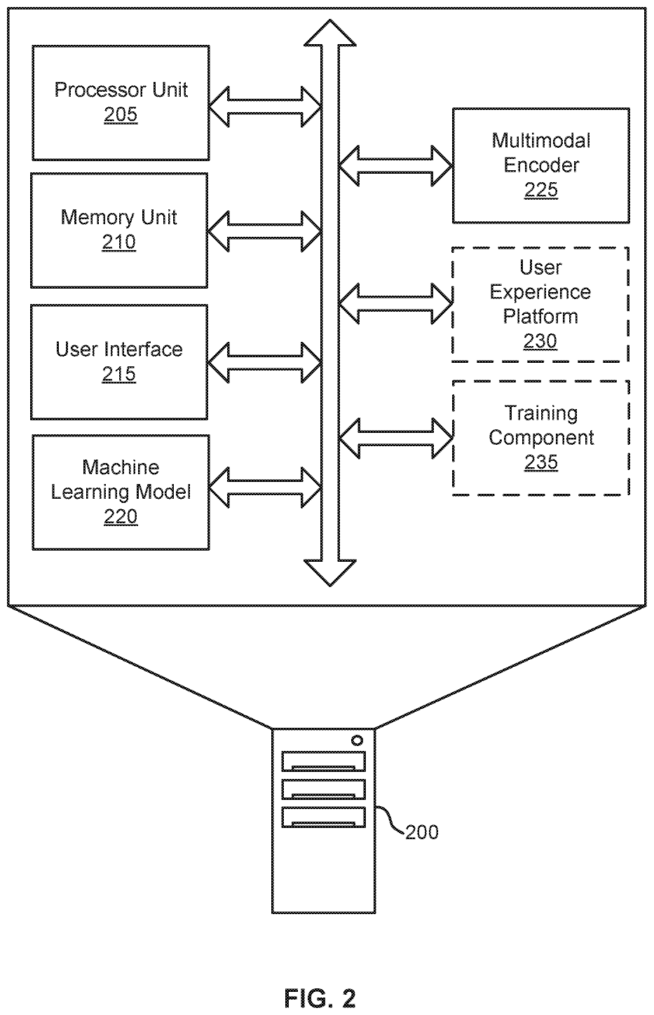

In some cases, data processing apparatus 115 generates a response to the query using a machine learning model (such as the machine learning model described with reference to FIGS. 2 and 4). In the example of FIG. 1, at least a portion of the response includes an opportunity. For example, as shown in FIG. 1, a first portion of the response includes natural language indicating a manner of achieving a goal of content provider 105 (“Based on your 2023 goal of increasing YoY bookings by 10%, you can leverage the emerging Solo Travel trend to support your goal with the following options.”) and a second portion of the response includes natural language indicating a suggested action for content provider 105 to take (“Generate a digital campaign to drive Loyalty Club bookings”) and language further describing the suggested action (“Drive bookings with a dynamic campaign targeting Loyalty Members who fall into the Solo Travelers profile with highly personalized content and journeys”). In the example of FIG. 1, the portions of the response are provided in a formatted area of the user interface, and corresponding visual elements are also displayed within the formatted area. In some cases, a portion of the response includes an instruction to the user interface or to a component of the data processing system (such as a user experience platform as described with reference to FIGS. 2 and 4) to provide the first and second portions of the response within the formatted area and to provide the corresponding visual elements.

Content provider device 110 is an example of, or includes aspects of, the corresponding element described with reference to FIG. 4. According to some aspects, content provider device 110 is a personal computer, laptop computer, mainframe computer, palmtop computer, personal assistant, mobile device, or any other suitable processing apparatus. In some examples, content provider device 110 includes software that displays a user interface (e.g., a graphical user interface) provided by data processing apparatus 115. In some aspects, the user interface allows information (such as an image, a prompt, etc.) to be communicated between content provider 105 and data processing apparatus 115.

According to some aspects, a content provider device user interface enables content provider 105 to interact with content provider device 110. In some embodiments, the content provider device user interface includes an audio device, such as an external speaker system, an external display device such as a display screen, or an input device (e.g., a remote-control device interfaced with the user interface directly or through an I/O controller module). In some cases, the content provider device user interface is a graphical user interface.

Data processing apparatus 115 is an example of, or includes aspects of, the corresponding element described with reference to FIG. 2. According to some aspects, data processing apparatus 115 includes a computer-implemented network. In some embodiments, the computer-implemented network includes a machine learning model (such as the machine learning model and/or the multimodal encoder described with reference to FIG. 2). In some embodiments, data processing apparatus 115 also includes one or more processors, a memory subsystem, a communication interface, an I/O interface, one or more user interface components, and a bus. Additionally, in some embodiments, data processing apparatus 115 communicates with content provider device 110 and database 125 via cloud 120.

In some cases, data processing apparatus 115 is implemented on a server. A server provides one or more functions to content providers linked by way of one or more of various networks, such as cloud 120. In some cases, the server includes a single microprocessor board, which includes a microprocessor responsible for controlling all aspects of the server. In some cases, the server uses microprocessor and protocols to exchange data with other devices or content providers on one or more of the networks via hypertext transfer protocol (HTTP), simple mail transfer protocol (SMTP), file transfer protocol (FTP), simple network management protocol (SNMP), or other protocols. In some cases, the server is configured to send and receive hypertext markup language (HTML) formatted files (e.g., for displaying web pages). In various embodiments, the server comprises a general-purpose computing device, a personal computer, a laptop computer, a mainframe computer, a supercomputer, or any other suitable processing apparatus.

Further detail regarding the architecture of data processing apparatus 115 is provided with reference to FIGS. 2-4. Further detail regarding a process for data processing is provided with reference to FIGS. 5-13. Further detail regarding a process for training a machine learning model is provided with reference to FIG. 14.

Cloud 120 is a computer network configured to provide on-demand availability of computer system resources, such as data storage and computing power. In some examples, cloud 120 provides resources without active management by a content provider. The term “cloud” is sometimes used to describe data centers available to many content providers over the Internet.

Some large cloud networks have functions distributed over multiple locations from central servers. A server is designated an edge server if it has a direct or close connection to a content provider. In some cases, cloud 120 is limited to a single organization. In other examples, cloud 120 is available to many organizations.

In one example, cloud 120 includes a multi-layer communications network comprising multiple edge routers and core routers. In another example, cloud 120 is based on a local collection of switches in a single physical location. According to some aspects, cloud 120 provides communications between content provider device 110, data processing apparatus 115, and database 125.

Database 125 is an example of, or includes aspects of, the corresponding element described with reference to FIG. 4. Database 125 is an organized collection of data. In an example, database 125 stores data in a specified format known as a schema. According to some aspects, database 125 is structured as a single database, a distributed database, multiple distributed databases, or an emergency backup database. In some cases, a database controller manages data storage and processing in database 125 via manual interaction or automatically without manual interaction. According to some aspects, database 125 is external to data processing apparatus 115 and communicates with data processing apparatus 115 via cloud 120. According to some aspects, database 125 is included in data processing apparatus 115.

FIG. 2 shows an example of a data processing apparatus 200 according to aspects of the present disclosure. Data processing apparatus 200 is an example of, or includes aspects of, the corresponding element described with reference to FIG. 1. In one aspect, data processing apparatus 200 includes processor unit 205, memory unit 210, user interface 215, machine learning model 220, multimodal encoder 225, user experience platform 230, and training component 235.

Processor unit 205 includes one or more processors. A processor is an intelligent hardware device, such as a general-purpose processing component, a digital signal processor (DSP), a central processing unit (CPU), a graphics processing unit (GPU), a microcontroller, an application specific integrated circuit (ASIC), a field programmable gate array (FPGA), a programmable logic device, a discrete gate or transistor logic component, a discrete hardware component, or any combination thereof.

In some cases, processor unit 205 is configured to operate a memory array using a memory controller. In other cases, a memory controller is integrated into processor unit 205. In some cases, processor unit 205 is configured to execute computer-readable instructions stored in memory unit 210 to perform various functions. In some aspects, processor unit 205 includes special purpose components for modem processing, baseband processing, digital signal processing, or transmission processing.

Memory unit 210 includes one or more memory devices. Examples of a memory device include random access memory (RAM), read-only memory (ROM), or a hard disk. Examples of memory devices include solid state memory and a hard disk drive. In some examples, memory is used to store computer-readable, computer-executable software including instructions that, when executed, cause at least one processor of processor unit 205 to perform various functions described herein.

In some cases, memory unit 210 includes a basic input/output system (BIOS) that controls basic hardware or software operations, such as an interaction with peripheral components or devices. In some cases, memory unit 210 includes a memory controller that operates memory cells of memory unit 210. For example, in some cases, the memory controller includes a row decoder, column decoder, or both. In some cases, memory cells within memory unit 210 store information in the form of a logical state.

User interface 215 is an example of, or includes aspects of, the corresponding element described with reference to FIGS. 4, and 8-13. According to some aspects, user interface 215 provides for communication between a content provider device (such as the content provider device described with reference to FIG. 1) and data processing apparatus 200. For example, in some cases, user interface 215 is a graphical user interface (GUI) provided on the content provider device by data processing apparatus 200.

According to some aspects, user interface 215 receives a query from a content provider about a chart that includes information related to a domain. In some examples, user interface 215 provides at least a portion of a response to the content provider. In some examples, user interface 215 displays a visual element to the content provider in response to a query. In some examples, user interface 215 displays at least a portion of an initial response. In some aspects, the portion of the initial response indicates a source of information from a corpus of documents. In some aspects, the portion of the initial response includes a natural language response describing a data trend.

Machine learning model 220 is an example of, or includes aspects of, the corresponding element described with reference to FIG. 4. According to some aspects, machine learning model 220 is implemented as software stored in memory unit 210 and executable by processor unit 205, as firmware, as one or more hardware circuits, or as a combination thereof. In some cases, machine learning model 220 is included in user experience platform 230. According to some aspects, machine learning model 220 comprises one or more artificial neural networks (ANNs) designed and/or trained to generate a text output in response to an input (such as text or an embedding).

An ANN is a hardware component or a software component that includes a number of connected nodes (i.e., artificial neurons) that loosely correspond to the neurons in a human brain. Each connection, or edge, transmits a signal from one node to another (like the physical synapses in a brain). When a node receives a signal, it processes the signal and then transmits the processed signal to other connected nodes.

In some cases, the signals between nodes comprise real numbers, and the output of each node is computed by a function of the sum of its inputs. In some examples, nodes determine their output using other mathematical algorithms, such as selecting the max from the inputs as the output, or any other suitable algorithm for activating the node. Each node and edge are associated with one or more node weights that determine how the signal is processed and transmitted.

In ANNs, a hidden (or intermediate) layer includes hidden nodes and is located between an input layer and an output layer. Hidden layers perform nonlinear transformations of inputs entered into the network. Each hidden layer is trained to produce a defined output that contributes to a joint output of the output layer of the ANN. Hidden representations are machine-readable data representations of an input that are learned from hidden layers of the ANN and are produced by the output layer. As the understanding of the ANN of the input improves as the ANN is trained, the hidden representation is progressively differentiated from earlier iterations.

During a training process of an ANN, the node weights are adjusted to improve the accuracy of the result (i.e., by minimizing a loss which corresponds in some way to the difference between the current result and the target result). The weight of an edge increases or decreases the strength of the signal transmitted between nodes. In some cases, nodes have a threshold below which a signal is not transmitted at all. In some examples, the nodes are aggregated into layers. Different layers perform different transformations on their inputs. The initial layer is known as the input layer and the last layer is known as the output layer. In some cases, signals traverse certain layers multiple times.

According to some aspects, machine learning model 220 includes machine learning parameters stored in memory unit 210. Machine learning parameters are variables that provide a behavior and characteristics of a machine learning model. In some cases, machine learning parameters are learned or estimated from training data and are used to make predictions or perform tasks based on learned patterns and relationships in the data.

In some cases, machine learning parameters are adjusted during a training process to minimize a loss function or to maximize a performance metric. The goal of the training process is to find optimal values for the parameters that allow the machine learning model to make accurate predictions or perform well on a given task.

For example, during the training process, an algorithm adjusts machine learning parameters to minimize an error or loss between predicted outputs and actual targets according to optimization techniques like gradient descent, stochastic gradient descent, or other optimization algorithms. Once the machine learning parameters are learned from the training data, the machine learning parameters are used to make predictions on new, unseen data.

In some cases, parameters of an ANN include weights and biases associated with each neuron in the ANN that control a strength of connections between neurons and influence the ability of the ANN to capture complex patterns in data.

According to some aspects, machine learning model 220 comprises a large language model. A large language model is a machine learning model that is designed and/or trained to learn statistical patterns and structures of human language. Large language models are capable of a wide range of language-related tasks such as text completion, question answering, translation, summarization, and creative writing, in response to a prompt. In some cases, the term “large” refers to a size and complexity of the large language model, usually measured in terms of a number of parameters of the large language model, where more parameters allow a large language model to understand more intricate language patterns and generate more nuanced and coherent text.

In some cases, the large language model comprises a sequence-to-sequence (seq2seq) model. A seq2seq model comprises one or more ANNs configured to transform a given sequence of elements, such as a sequence of words in a sentence, into another sequence using sequence transformation.

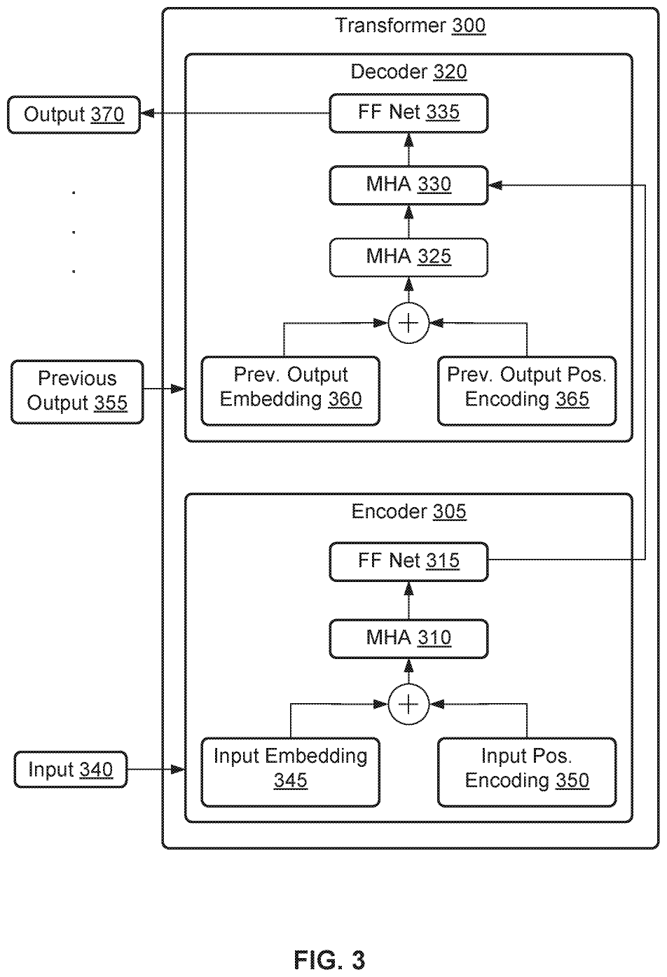

In some cases, machine learning model 220 comprises one or more transformers (such as the transformer described with reference to FIG. 3). In some cases, a transformer comprises one or more ANNs comprising attention mechanisms that enable the transformer to weigh an importance of different words or tokens within a sequence. In some cases, a transformer processes entire sequences simultaneously in parallel, making the transformer highly efficient and allowing the transformer to capture long-range dependencies more effectively.

In some cases, a transformer comprises an encoder-decoder structure. In some cases, the encoder of the transformer processes an input sequence and encodes the input sequence into a set of high-dimensional representations. In some cases, the decoder of the transformer generates an output sequence based on the encoded representations and previously generated tokens. In some cases, the encoder and the decoder are composed of multiple layers of self-attention mechanisms and feed-forward ANNs.

In some cases, the self-attention mechanism allows the transformer to focus on different parts of an input sequence while computing representations for the input sequence. In some cases, the self-attention mechanism captures relationships between words of a sequence by assigning attention weights to each word based on a relevance to other words in the sequence, thereby enabling the transformer to model dependencies regardless of a distance between words.

An attention mechanism is a key component in some ANN architectures, particularly ANNs employed in natural language processing (NLP) and sequence-to-sequence tasks, that allows an ANN to focus on different parts of an input sequence when making predictions or generating output.

NLP refers to techniques for using computers to interpret or generate natural language. In some cases, NLP tasks involve assigning annotation data such as grammatical information to words or phrases within a natural language expression. Different classes of machine-learning algorithms have been applied to NLP tasks. Some algorithms, such as decision trees, utilize hard if-then rules. Other systems use neural networks or statistical models which make soft, probabilistic decisions based on attaching real-valued weights to input features. In some cases, these models express the relative probability of multiple answers.

Some sequence models (such as recurrent neural networks) process an input sequence sequentially, maintaining an internal hidden state that captures information from previous steps. However, in some cases, this sequential processing leads to difficulties in capturing long-range dependencies or attending to specific parts of the input sequence.

The attention mechanism addresses these difficulties by enabling an ANN to selectively focus on different parts of an input sequence, assigning varying degrees of importance or attention to each part. The attention mechanism achieves the selective focus by considering a relevance of each input element with respect to a current state of the ANN.

In some cases, an ANN employing an attention mechanism receives an input sequence and maintains its current state, which represents an understanding or context. For each element in the input sequence, the attention mechanism computes an attention score that indicates the importance or relevance of that element given the current state. The attention scores are transformed into attention weights through a normalization process, such as applying a softmax function. The attention weights represent the contribution of each input element to the overall attention. The attention weights are used to compute a weighted sum of the input elements, resulting in a context vector. The context vector represents the attended information or the part of the input sequence that the ANN considers most relevant for the current step. The context vector is combined with the current state of the ANN, providing additional information and influencing subsequent predictions or decisions of the ANN.

In some cases, by incorporating an attention mechanism, an ANN dynamically allocates attention to different parts of the input sequence, allowing the ANN to focus on relevant information and capture dependencies across longer distances.

In some cases, calculating attention involves three basic steps. First, a similarity between a query vector Q and a key vector K obtained from the input is computed to generate attention weights. In some cases, similarity functions used for this process include dot product, splice, detector, and the like. Next, a softmax function is used to normalize the attention weights. Finally, the attention weights are weighed together with their corresponding values V. In the context of an attention network, the key K and value V are typically vectors or matrices that are used to represent the input data. The key K is used to determine which parts of the input the attention mechanism should focus on, while the value V is used to represent the actual data being processed.

According to some aspects, machine learning model 220 generates a response to the query based on the chart and the corpus of documents in the domain, where the response includes information from the corpus of documents. In some aspects, machine learning model 220 is trained to answer questions in the domain using the corpus of documents as training data. In some examples, machine learning model 220 generates an initial response based on the prompt. In some examples, machine learning model 220 generates the response based on the subsequent prompt. In some aspects, the portion of the response suggests one or more content provider actions.

According to some aspects, multimodal encoder 225 is implemented as software stored in memory unit 210 and executable by processor unit 205, as firmware, as one or more hardware circuits, or as a combination thereof. According to some aspects, multimodal encoder 225 comprises one or more artificial neural networks (ANNs) designed and/or trained to generate an embedding for an input. According to some aspects, multimodal encoder 225 comprises multimodal encoder parameters stored in memory unit 210.

According to some aspects, multimodal encoder 225 comprises a text encoder comprising one ore more ANNs (such as a recurrent neural network or a transformer) that are designed and/or trained to generate a text embedding in a text embedding space or a multimodal embedding space based on a text input.

A recurrent neural network (RNN) is a class of ANN in which connections between nodes form a directed graph along an ordered (i.e., a temporal) sequence. This enables an RNN to model temporally dynamic behavior such as predicting what element should come next in a sequence. Thus, an RNN is suitable for tasks that involve ordered sequences such as text recognition (where words are ordered in a sentence). In some cases, an RNN includes a finite impulse recurrent network (characterized by nodes forming a directed acyclic graph) or an infinite impulse recurrent network (characterized by nodes forming a directed cyclic graph).

According to some aspects, multimodal encoder 225 comprises a chart encoder comprising one or more ANNs (such as a convolution neural network or a transformer) configured to generate a chart embedding in a chart embedding space or a multimodal embedding space based on a chart input.

A convolution neural network (CNN) is a class of ANN that is commonly used in computer vision or image classification systems. In some cases, a CNN enables processing of digital images with minimal pre-processing. In some cases, a CNN is characterized by the use of convolutional (or cross-correlational) hidden layers. These layers apply a convolution operation to the input before signaling the result to the next layer. In some cases, each convolutional node processes data for a limited field of input (i.e., the receptive field). In some cases, during a forward pass of the CNN, filters at each layer are convolved across the input volume, computing the dot product between the filter and the input. In some cases, during a training process, the filters are modified so that they activate when they detect a particular feature within the input.

According to some aspects, multimodal encoder 225 comprises a multimodal encoder comprising one or more ANNs (such as a CLIP model) configured to generate an embedding in a multimodal embedding space based on an input, such as text or an image (e.g., a chart).

Contrastive Language-Image Pre-Training (CLIP) is an ANN architecture that is trained to efficiently learn visual concepts from natural language supervision. In some cases, CLIP is instructed in natural language to perform a variety of classification benchmarks without directly optimizing for the benchmarks' performance, in a manner building on “zero-shot” or zero-data learning. In some cases, CLIP learns from unfiltered, highly varied, and highly noisy data, such as text paired with images found across the Internet, in a similar but more efficient manner to zero-shot learning, thus reducing the need for expensive and large labeled datasets.

In some cases, a CLIP model is applied to nearly arbitrary visual classification tasks so that the model predicts a likelihood of a text description being paired with a particular image, removing the need for content providers to design their own classifiers and the need for task-specific training data. For example, in some cases, a CLIP model is applied to a new task by inputting names of the task's visual concepts to the model's text encoder. The model then outputs a linear classifier of CLIP's visual representations.

According to some aspects, multimodal encoder 225 encodes the query to obtain a query embedding, where the response is generated based on the query embedding. In some examples, multimodal encoder 225 encodes the chart using a multimodal encoder 225 to obtain a chart embedding, where the response is generated based on the chart embedding.

User experience platform 230 is an example of, or includes aspects of, the corresponding element described with reference to FIG. 4. According to some aspects, user experience platform 230 is implemented as software stored in memory unit 210 and executable by processor unit 205, as firmware, as one or more hardware circuits, or as a combination thereof.

According to some aspects, user experience platform 230 is omitted from data processing apparatus 200 and is implemented in at least one apparatus separate from data processing apparatus 200 (for example, at least one apparatus comprised in a cloud, such as the cloud described with reference to FIG. 1). According to some aspects, the separate apparatus comprising user experience platform 230 communicates with data processing apparatus 200 (for example, via the cloud) to perform the functions of user experience platform 230 described herein.

For example, in some cases, data processing apparatus 200 is implemented as an edge server in a data processing system (such as the content generation system described with reference to FIGS. 1 and 4), user experience platform 230 is included in a central server of the data processing system, and data processing apparatus 200 communicates with the central server to implement the functions of user experience platform 230 described herein.

According to some aspects, user experience platform 230 includes a set of creative, analytics, social, advertising, media optimization, targeting, Web experience management, journey orchestration and content management tools. In some cases, user experience platform 230 includes one or more of a graphic design component providing image generation and/or editing capabilities, a video editing component, a web development component, and a photography component. In some cases, user experience platform 230 comprises one or more of an enterprise content management component; a digital asset management component; an enterprise content distribution component that manages direct content distribution campaigns, leads, resources, user data, and analytics, and allows content providers to design and orchestrate targeted and personalized campaigns via channels such as direct mail, e-mail, SMS, and MMS; a data management component for data modeling and predictive analytics; and a web analytics system that provides web metrics, dimensions, and allows content provider to define tags implemented in webpage for web tracking to provide customized dimensions, metrics, segmentations, content provider reports, and dashboards.

In some cases, user experience platform 230 has comprehensive end-to-end capabilities with content distribution-specific technology across conceptualization, execution, and insights to merge with machine learning model 220 and generative machine learning experiences. In some cases, user experience platform 230 builds a cohesive user view, supporting but not limited to analytics, digital advertising, email, user data management, social media, call centers, and commerce. In some cases, user experience platform 230 consolidates, identifies, and builds full profiles from datasets that provide differentiating data for generating content that benefits from personalization.

According to some aspects, user experience platform 230 comprises one or more ANNs, and one or more components of user experience platform 230 are implemented via the one or more ANNs.

According to some aspects, user experience platform 230 generates a visual element corresponding to the response. In some examples, user experience platform 230 identifies chart data associated with the chart, where the response is based on the chart data. In some examples, user experience platform 230 identifies a data trend in the domain. In some examples, user experience platform 230 generates a prompt based on the data trend, where the prompt includes information included in the corpus of documents. In some examples, user experience platform 230 generates a subsequent prompt based on the query and the initial response. In some aspects, the subsequent prompt further includes one or more of content provider data for the content provider and user data for one or more users associated with the content provider.

According to some aspects, training component 235 is implemented as software stored in memory unit 210 and executable by processor unit 205, as firmware, as one or more hardware circuits, or as a combination thereof. According to some aspects, training component 235 is omitted from data processing apparatus 200 and is implemented in at least one apparatus separate from data processing apparatus 200 (for example, at least one apparatus comprised in a cloud, such as the cloud described with reference to FIG. 1). According to some aspects, the separate apparatus comprising training component 235 communicates with data processing apparatus 200 (for example, via the cloud) to perform the functions of training component 235 described herein.

According to some aspects, training component 235 obtains training data including a corpus of documents from a domain, chart data from the domain, a training query, and a ground-truth response to the training query. In some examples, training component 235 trains machine learning model 220 to answer domain-specific questions in the domain using the training data. In some examples, training component 235 trains machine learning model 220 to answer the domain-specific questions based on a chart embedding. In some examples, training component 235 trains machine learning model 220 to generate a chart using the training data.

FIG. 3 shows an example of a transformer 300 according to aspects of the present disclosure. The example shown includes transformer 300, encoder 305, decoder 320, input 340, input embedding 345, input positional encoding 350, previous output 355, previous output embedding 360, previous output positional encoding 365, and output 370.

In some cases, encoder 305 includes multi-head self-attention sublayer 310 and feed-forward network sublayer 315. In some cases, decoder 320 includes first multi-head self-attention sublayer 325, second multi-head self-attention sublayer 330, and feed-forward network sublayer 335.

According to some aspects, a machine learning model (such as the machine learning model described with reference to FIGS. 2 and 4) comprises transformer 300. In some cases, encoder 305 is configured to map input 340 (for example, a query or a prompt comprising a sequence of words or tokens) to a sequence of continuous representations that are fed into decoder 320. In some cases, decoder 320 generates output 370 (e.g., a prediction of an output sequence of words or tokens) based on the output of encoder 305 and previous output 355 (e.g., a previously predicted output sequence), which allows for the use of autoregression.

For example, in some cases, encoder 305 parses input 340 into tokens and vectorizes the parsed tokens to obtain input embedding 345, and adds input positional encoding 350 (e.g., positional encoding vectors for input 340 of a same dimension as input embedding 345) to input embedding 345. In some cases, input positional encoding 350 includes information about relative positions of words or tokens in input 340.

In some cases, encoder 305 comprises one or more encoding layers (e.g., six encoding layers) that generate contextualized token representations, where each representation corresponds to a token that combines information from other input tokens via self-attention mechanism. In some cases, each encoding layer of encoder 305 comprises a multi-head self-attention sublayer (e.g., multi-head self-attention sublayer 310). In some cases, the multi-head self-attention sublayer implements a multi-head self-attention mechanism that receives different linearly projected versions of queries, keys, and values to produce outputs in parallel. In some cases, each encoding layer of encoder 305 also includes a fully connected feed-forward network sublayer (e.g., feed-forward network sublayer 315) comprising two linear transformations surrounding a Rectified Linear Unit (ReLU) activation:

$$FFN ( x ) = R e L U ( {W}_{1} x + {b}_{1} ) {W}_{2} + {b}_{2} \qquad ( 1 )$$

In some cases, each layer employs different weight parameters (W1, W2) and different bias parameters (b1, b2) to apply a same linear transformation each word or token in input 340.

In some cases, each sublayer of encoder 305 is followed by a normalization layer that normalizes a sum computed between a sublayer input x and an output sublayer(x) generated by the sublayer:

$$layernorm ( x + sublayer ( x ) ) \qquad ( 2 )$$

In some cases, encoder 305 is bidirectional because encoder 305 attends to each word or token in input 340 regardless of a position of the word or token in input 340.

In some cases, decoder 320 comprises one or more decoding layers (e.g., six decoding layers). In some cases, each decoding layer comprises three sublayers including a first multi-head self-attention sublayer (e.g., first multi-head self-attention sublayer 325), a second multi-head self-attention sublayer (e.g., second multi-head self-attention sublayer 330), and a feed-forward network sublayer (e.g., feed-forward network sublayer 335). In some cases, each sublayer of decoder 320 is followed by a normalization layer that normalizes a sum computed between a sublayer input x and an output sublayer(x) generated by the sublayer.

In some cases, decoder 320 generates previous output embedding 360 of previous output 355 and adds previous output positional encoding 365 (e.g., position information for words or tokens in previous output 355) to previous output embedding 360. In some cases, each first multi-head self-attention sublayer receives the combination of previous output embedding 360 and previous output positional encoding 365 and applies a multi-head self-attention mechanism to the combination. In some cases, for each word in an input sequence, each first multi-head self-attention sublayer of decoder 320 attends only to words preceding the word in the sequence, and so transformer 300's prediction for a word at a particular position only depends on known outputs for a word that came before the word in the sequence. For example, in some cases, each first multi-head self-attention sublayer implements multiple single-attention functions in parallel by introducing a mask over values produced by the scaled multiplication of matrices Q and K by suppressing matrix values that would otherwise correspond to disallowed connections.

In some cases, each second multi-head self-attention sublayer implements a multi-head self-attention mechanism similar to the multi-head self-attention mechanism implemented in each multi-head self-attention sublayer of encoder 305 by receiving a query Q from a previous sublayer of decoder 320 and a key K and a value V from the output of encoder 305, allowing decoder 320 to attend to each word in the input 340.

In some cases, each feed-forward network sublayer implements a fully connected feed-forward network similar to feed-forward network sublayer 315. In some cases, the feed-forward network sublayers are followed by a linear transformation and a softmax to generate a prediction of output 370 (e.g., a prediction of a next word or token in a sequence of words or tokens). Accordingly, in some cases, transformer 300 generates a response as described herein based on a predicted sequence of words or tokens.

FIG. 4 shows an example of data flow in a data processing system 400 according to aspects of the present disclosure. The example shown includes content provider device 405, query 410, user interface 415, user experience platform 420, database 425, prompt 430, machine learning model 435, and response 440.

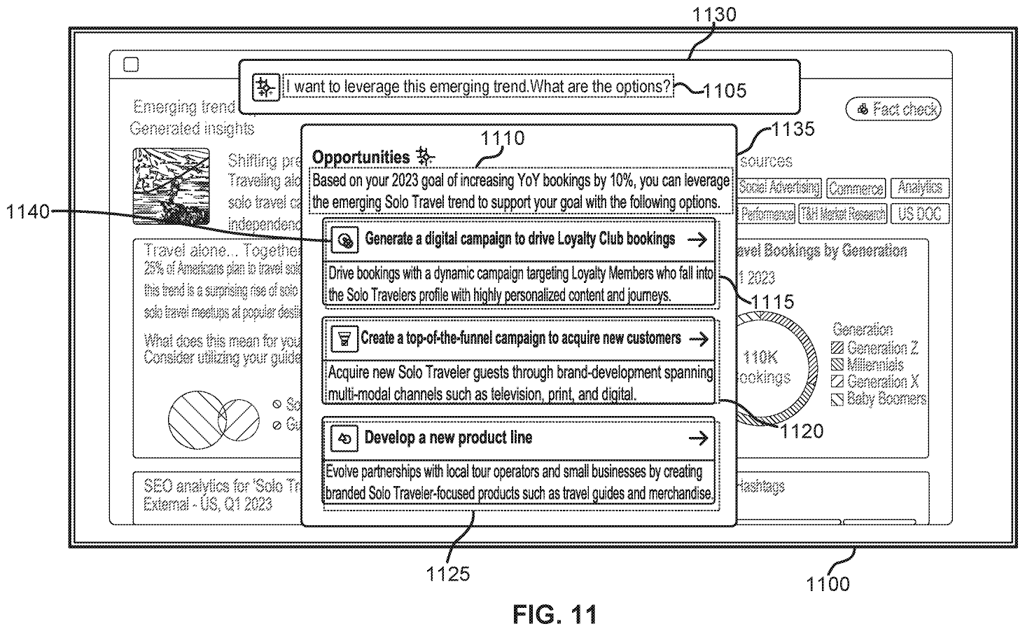

Data processing system 400 is an example of, or includes aspects of, the corresponding element described with reference to FIG. 1. Content provider device 405 is an example of, or includes aspects of, the corresponding element described with reference to FIG. 1. Query 410 is an example of, or includes aspects of, the corresponding element described with reference to FIG. 11. User interface 415 is an example of, or includes aspects of, the corresponding element described with reference to FIGS. 2 and 8-13. User experience platform 420 is an example of, or includes aspects of, the corresponding element described with reference to FIG. 2. Database 425 is an example of, or includes aspects of, the corresponding element described with reference to FIG. 1. Machine learning model 435 is an example of, or includes aspects of, the corresponding element described with reference to FIG. 2.

Referring to FIG. 4, according to some aspects, a content provider provides query 410 to user interface 415 displayed on content provider device 405 by a data processing apparatus of data processing system 400 (such as the data processing apparatus described with reference to FIGS. 1 and 2). In some cases, query 410 relates to information displayed on user interface 415. In some cases, the information displayed on user interface 415 includes a chart.

In some cases, user interface 415 provides query 410 to user experience platform 420. In some cases, user experience platform 420 retrieves data relating to one or more of query 410, the content provider, and the information displayed on user interface 415 from one or more of database 425 and another data source (such as the Internet). In some cases, user experience platform 420 generates prompt 430 based on one or more of query 410, the information displayed on user interface 415, and the data retrieved from database 425 and/or the other data source.

In some cases, user experience platform 420 provides prompt 430 to machine learning model 435. In some cases, machine learning model 435 generates response 440 based on prompt 430. In some cases, user interface 415 displays at least a portion of response 440 on content provider device 405. In some cases, user interface 415 also displays elements one or more visual elements generated by user experience platform 420 and relating to one or more of prompt 430 and response 440.

### Data Processing

A method for data processing is described with reference to FIGS. 5-13. One or more aspects of the method include receiving, from a content provider via a user interface, a query about a chart that includes information related to a domain; generating a response to the query based on the chart and a corpus of documents in the domain, wherein the response includes information from the corpus of documents; and providing at least a portion of the response to the content provider. In some aspects, the portion of the response suggests one or more content provider actions. In some aspects, the machine learning model is trained to answer questions in the domain using the corpus of documents as training data.

Some examples of the method further include encoding the query to obtain a query embedding, wherein the response is generated based on the query embedding. Some examples of the method further include encoding the chart using a multimodal encoder to obtain a chart embedding, wherein the response is generated based on the chart embedding.

Some examples of the method further include generating a visual element based on the response. Some examples further include displaying the visual element to the content provider in response to the query. Some examples of the method further include identifying chart data associated with the chart, wherein the response is based on the chart data.

Some examples of the method further include identifying a data trend in the domain. Some examples further include generating a prompt based on the data trend, wherein the prompt comprises information included in the corpus of documents. Some examples further include generating an initial response based on the prompt. Some examples further include displaying at least a portion of the initial response.

Some examples of the method further include generating a subsequent prompt based on the query and the initial response. Some examples further include generating the response based on the subsequent prompt. In some aspects, the subsequent prompt further comprises one or more of content provider data for the content provider and user data for one or more users associated with the content provider. In some aspects, the portion of the initial response indicates a source of information from the corpus of documents. In some aspects, the portion of the initial response comprises a natural language response describing the data trend.

FIG. 5 shows an example of a method 500 for generating an insight and an opportunity according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

Referring to FIG. 5, a data processing system (such as the data processing system described with reference to FIG. 1) generates insights and opportunities for a content provider (such as the content provider described with reference to FIG. 1) using machine learning based on data such as external data, user historical data, and/or data presented to the content provider by the data processing system in a graphical user interface.

In some cases, a machine learning model of the data processing system (such as the machine learning model described with reference to FIGS. 2 and 4) is refined or prompted with data to generate a response (such as an insight or an opportunity) to a content provider-provided query (such as “what are some trends or anomalies of relevance to our business”) and to provide supporting facts for the response. In some cases, the machine learning model provides an ability to understand the semantics of the query and to respond with relevant information gleaned from the prompt data.

In some cases, a machine learning model of the data processing system (such as the machine learning model described with reference to FIGS. 2 and 4) synthesizes, summarizes, and/or curates from external and/or internal data sources to generate an insight. In some cases, the data sources are inclusive of at least one of a foundational enterprise/content distribution focus and a unique content provider-specific foundation.

Examples of data having a foundational enterprise/content distribution focus include publicly available competitor information and announcements, market research reports, brand awareness and perception data, company and industry data, demographic data, seasonal data, macroeconomic data, microeconomic data, and data relating to world events.

Examples of data having a content provider-specific foundation include user and segmentation data, content affinity data based on historical responses to content distribution campaigns, user journey preferences (such as frequency, channels, and content preferences) based on historical performance of content distribution campaigns, share partner or purchased data, historical content distribution campaign details and performance data, brand guidelines and historical content experiences, previous experiments and results, and user research, such as market research and churn analysis.

In some cases, the data processing apparatus provides the insight via user interface of the data processing apparatus (such as the user interface described with reference to FIGS. 2 and 4) in various forms, including data stories, charts, visuals, presentations, or a combination thereof.

In some cases, the machine learning model is prompted to consider the insight and the external and/or internal data sources (such as historical performance, user preferences, market research, external world data, company knowledge data, or a combination thereof) to generate an opportunity. In some cases, the data processing apparatus presents the opportunity via the user interface in a simplified and conversational way.

In some cases, the data processing apparatus continuously identifies insights and opportunities and provides the generated insights and opportunities to the machine learning model as training data through feedback loops to optimize an accuracy and relevancy of the insights and opportunities.

At operation 505, the system identifies a data trend or a data anomaly. In some cases, the operations of this step refer to, or are performed by, a data processing apparatus as described with reference to FIGS. 1-2 and 4. For example, in some cases, a user experience platform of the data processing apparatus or the data processing system (such as the user experience platform described with reference to FIG. 2) interacts with the data processing apparatus to identify a trend or anomaly in data that the user experience platform monitors for the content provider (such as the data sources inclusive of at least one of the foundational enterprise/content distribution focus and the unique content provider-specific foundation).

In some cases, the data relates to one or more users or prospective users of the content provider. In some cases, the content provider identifies the data to be monitored. In some cases, the user experience platform identifies the data to be monitored based on the content provider. In some cases, the user experience platform is configured to identify the data trend based on a data trend threshold determined by one or more of the content provider and the user experience platform. In some cases, the data is included in a corpus of documents in a domain. In some cases, the corpus of documents includes a chart. In some cases, the corpus of documents includes a table.

At operation 510, the system generates an insight based on the data trend. In some cases, the operations of this step refer to, or are performed by, a data processing apparatus as described with reference to FIGS. 1-2 and 4. For example, in some cases, the user experience platform generates an insight prompt based on the identified data trend. In some cases, the insight prompt relates to the identified data trend. In some cases, the insight prompt includes one or more documents of the corpus of documents. In some cases, the insight prompt comprises natural language instructions for the machine learning model to generate an insight based on the insight prompt. In some cases, the insight prompt is generated according to a template.

In some cases, the machine learning model generates an insight based on the insight prompt. In some cases, the insight comprises natural language describing the data trend. In some cases, the insight comprises natural language including an analysis of the data trend. In some cases, the insight comprises natural language indicating a cause of the data trend. In some cases, the insight comprises natural language indicating a potential effect of the data trend.

In some cases, the data processing apparatus provides at least a portion of the insight to the content provider via a user interface displayed on a content provider device by the data processing apparatus. In some cases, the data processing apparatus provides a visual element corresponding to the response to the content provider via the user interface.

At operation 515, the content provider provides a query with respect to the insight. For example, in some cases, the content provider provides a text input to the user interface based on the at least portion of the insight displayed by the user interface. In some cases, the query is provided via a dialogue box of the user interface.

At operation 520, the system generates an opportunity based on the insight in response to the query. In some cases, the operations of this step refer to, or are performed by, a data processing apparatus as described with reference to FIGS. 1-2 and 4. For example, in some cases, the user experience platform generates a query prompt based on the query. In some cases, the query prompt includes the query. In some cases, the query prompt includes one or more documents of the corpus of documents. In some cases, the query prompt comprises natural language instructions for the machine learning model to generate an insight based on the insight prompt. In some cases, the query prompt is generated according to a template.

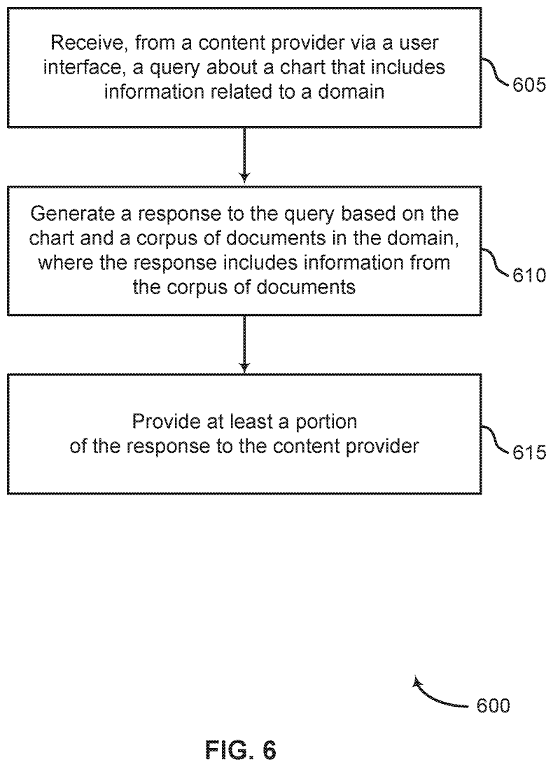

FIG. 6 shows an example of a method 600 for responding to a query according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

Referring to FIG. 6, according to some aspects, a data processing system generates a response to a query about a chart that includes information related to a domain. In some cases, the response is generated based on the chart and a corpus of documents in the domain.

At operation 605, the system receives, from a content provider via a user interface, a query about a chart that includes information related to a domain. In some cases, the operations of this step refer to, or are performed by, a user interface as described with reference to FIGS. 2, 4, and 8-13.

In some cases, the content provider provides the query. In some cases, a user experience platform of the data processing system (such as the user experience platform described with reference to FIGS. 2 and 4) generates the query in response to detecting a data trend or a data anomaly. In some cases, the user experience platform generates the query in response to providing an insight. In some cases, the query includes natural language. In some cases, the user experience platform displays a message via the user interface corresponding to a data trend, a data anomaly, or an insight, and the content provider provides the query by interacting with the message (such as by providing a content provider input to an element of the user interface associated with the message).

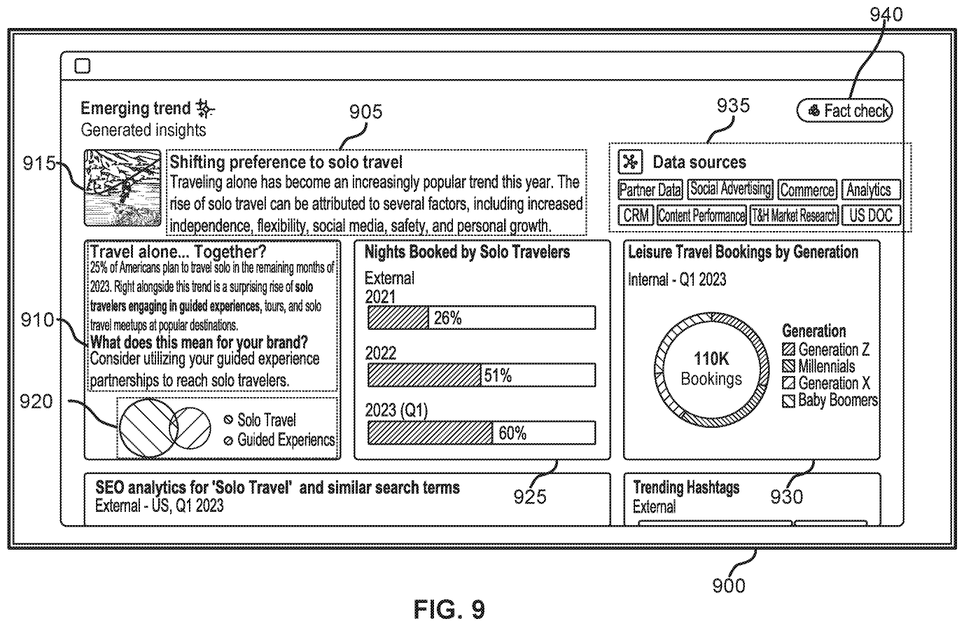

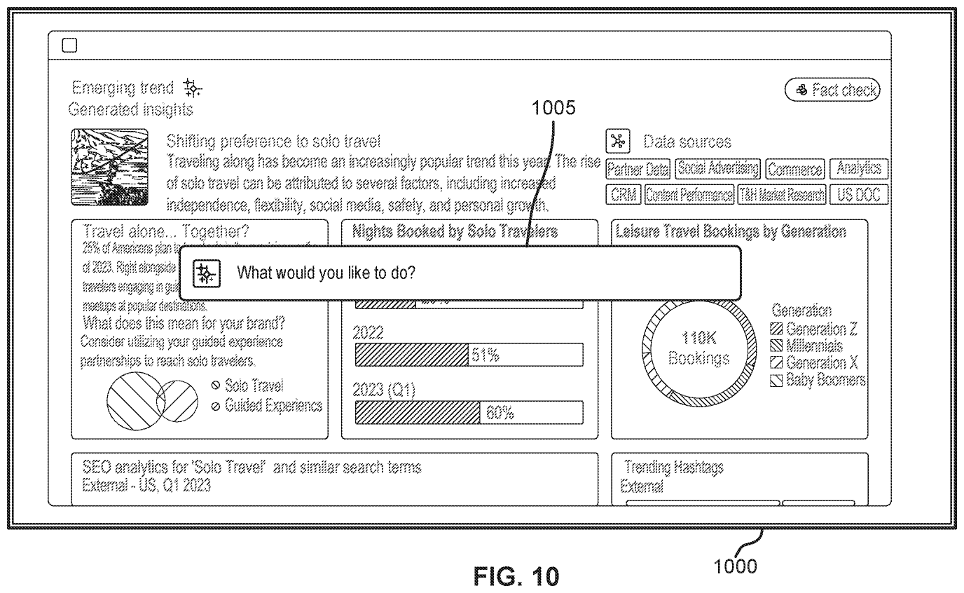

In some cases, the chart is displayed on a user interface provided by the data processing system. An example of information related to a domain is shown in FIG. 9. An example of a message corresponding to an insight relating to the information is shown in FIG. 10. An example of a query provided by a content provider in response to the message corresponding to the insight is provided with reference to FIG. 11.

At operation 610, the system generates a response to the query based on the chart and a corpus of documents in the domain, where the response includes information from the corpus of documents. In some cases, the operations of this step refer to, or are performed by, a machine learning model as described with reference to FIGS. 2 and 4. In some cases, the response is an “insight” as described herein. In some cases, the response is an “opportunity” as described herein.

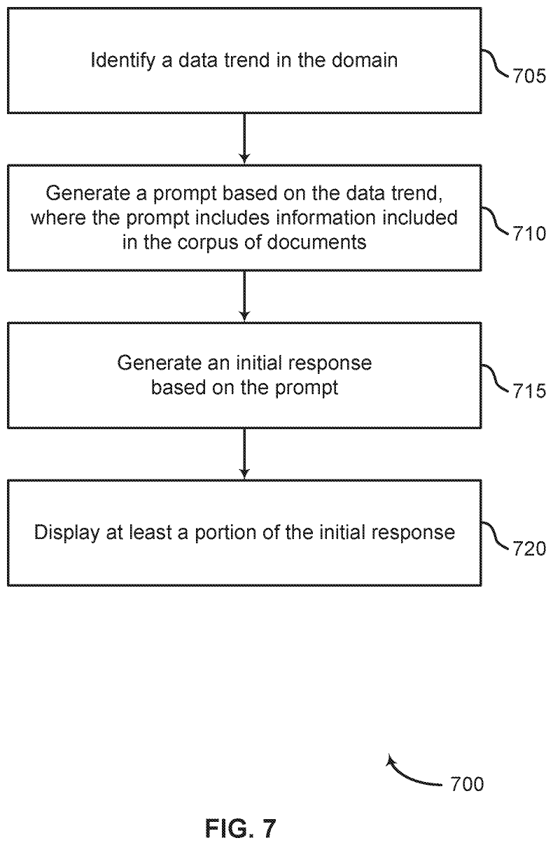

In some cases, the machine learning model is trained to answer questions in the domain using the corpus of documents as training data. In some cases, a multimodal encoder (such as the multimodal encoder described with reference to FIG. 2) encodes the query to obtain a query embedding. In some cases, the machine learning model receives the query embedding as input and generates the response based on the query embedding. In some cases, the user experience platform includes the query embedding in one or more prompts (such as the prompt or the subsequent prompt described with reference to FIG. 7).

In some cases, the multimodal encoder encodes the chart to obtain a chart embedding. In some cases, the machine learning model receives the chart embedding as input and generates the response based on the chart embedding. In some cases, the user experience platform includes the chart embedding in the prompt or the subsequent prompt.

In some cases, the user experience platform identifies chart data associated with the chart. In some cases, the user experience platform includes the chart data in the prompt or the subsequent prompt. In some cases, the machine learning model generates the response based on the chart data. In some cases, the machine learning model generates the response based on a prompt and a subsequent prompt as described with reference to FIG. 7.

In some cases, the user experience platform generates a visual element (such as a chart, an image, an icon, a presentation slide, a data story, etc.) corresponding to the response.

In some cases, the user experience platform generates the visual element using a generative machine learning model included in the user experience platform (such as a generative adversarial network, a diffusion model, or other suitable machine learning model). In some cases, the user experience platform generates the visual element using a visual element generation algorithm included in the user experience platform. In some cases, the user experience platform retrieves the visual element from a database (such as the database described with reference to FIG. 1) or from another data source (such as the Internet). In some cases, the response includes instructions to the user experience platform to generate and/or retrieve the visual element.

At operation 615, the system provides at least a portion of the response to the content provider. In some cases, the operations of this step refer to, or are performed by, a user interface as described with reference to FIGS. 2, 4, and 8-13. For example, in some cases, the portion of the response includes natural language. In some cases, the portion of the response includes natural language suggesting one or more actions (such as a suggested action for the content provider, or a suggested action for the data processing system). An example of one or more portions of a response is shown in FIG. 11. In some cases, the data processing system displays the visual element to the content provider in response to the query.

FIG. 7 shows an example of a method 700 for generating an initial response according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

At operation 705, the system identifies a data trend (or a data anomaly) in the domain. In some cases, the operations of this step refer to, or are performed by, a user experience platform as described with reference to FIGS. 2 and 4.

In some cases, the user experience platform is configured to monitor the domain by the content provider to detect the data trend or data anomaly. In some cases, the user experience platform is configured to provide a message to the content provider via the user interface when the data trend or the data anomaly is detected. In some cases, the content provider provides an instruction via the query to the user experience platform to identify the data trend or the data anomaly.

At operation 710, the system generates a prompt based on the data trend, where the prompt includes information included in the corpus of documents. In some cases, the operations of this step refer to, or are performed by, a user experience platform as described with reference to FIGS. 2 and 4.

In some cases, the user experience platform is configured to generate the prompt based on a prompt template including natural language, where the prompt template is selected based on the identification of the data trend or the data anomaly. In some cases, the prompt template is retrieved from a database (such as the database described with reference to FIG. 1).

In some cases, the prompt includes an instruction for the machine learning model to generate an initial response having content specified by the prompt. In some cases, the prompt includes an instruction for the machine learning model to generate the initial response based on information included in the prompt. For example, in some cases, the prompt includes the corpus of documents described with reference to FIG. 6.

In some cases, the prompt includes the query or the query embedding described with reference to FIG. 6. In some cases, the prompt includes the chart or the chart embedding described with reference to FIG. 6. In some cases, a multimodal encoder (such as the multimodal encoder described with reference to FIG. 2) encodes the prompt to obtain a prompt embedding. In some cases, the prompt includes content provider data for the content provider (such as a content provider identifier). In some cases, the prompt includes user data for one or more users associated with the content provider.

At operation 715, the system generates an initial response based on the prompt. In some cases, the operations of this step refer to, or are performed by, a machine learning model as described with reference to FIGS. 2 and 4.

For example, in some cases, the user experience platform provides the prompt or the prompt embedding to the machine learning model as input. In some cases, the machine learning model generates the initial response based on the prompt or the prompt embedding. In some cases, the initial response includes an “insight” as described herein. For example, in some cases, the initial response includes a natural language analysis of the data trend or data anomaly (such as an identification of a predicted cause or contributing factor for the data trend or data anomaly, a prediction of an effect of the data trend or the data anomaly, etc.). In some cases, the initial response includes a text instruction provided in an appropriate format (such as a programming language) for a different component (such as the user experience platform) to perform an action (such as generating or retrieving a visual element).

In some cases, the user experience platform generates a visual element (such as a chart, an image, an icon, a presentation slide, a data story, etc.) corresponding to the initial response. In some cases, the user experience platform generates the visual element using a generative machine learning model included in the user experience platform (such as a generative adversarial network, a diffusion model, or other suitable machine learning model).

In some cases, the user experience platform generates the visual element using a visual element generation algorithm included in the user experience platform. In some cases, the user experience platform generates the visual element by retrieving the visual element from a database (such as the database described with reference to FIG. 1) or from another data source (such as the Internet). In some cases, the initial response generates the visual element based on instructions included in the initial response. For example, in some cases, the initial response includes a visual element generation prompt.

In some cases, the initial response indicates a source of information from the corpus of documents. For example, in some cases, the initial response includes a natural language description of one or more documents that includes supporting evidence for the initial response.

At operation 720, the system displays at least a portion of the initial response. In some cases, the operations of this step refer to, or are performed by, a user interface as described with reference to FIGS. 2, 4, and 8-13.

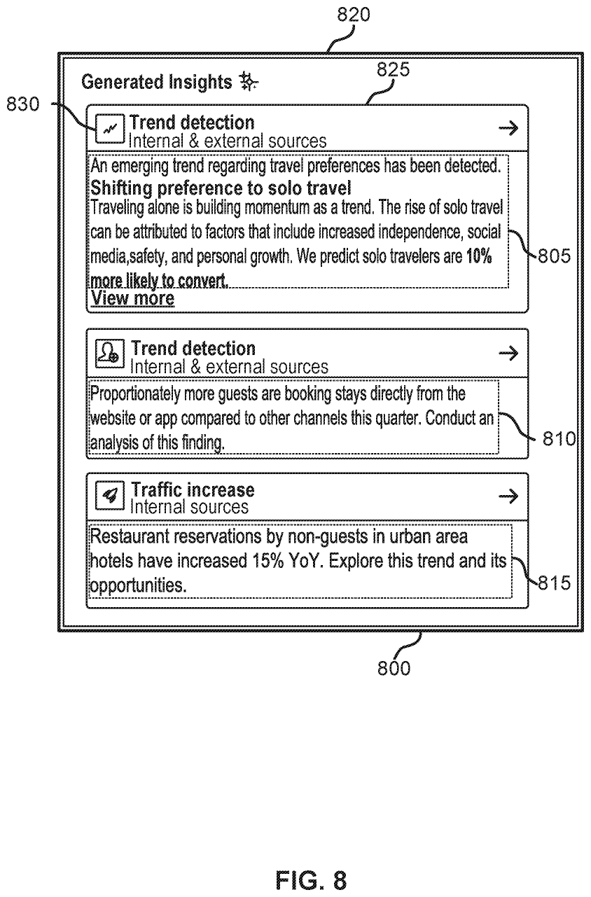

For example, in some cases, the user interface displays a portion of the response including natural language. In some cases, the user interface displays the visual element corresponding to the initial response. Examples of portions of an initial response and visual elements corresponding to the initial response are shown in FIGS. 8 and 9.

According to some aspects, the user experience platform generates a subsequent prompt based on the query and the initial response. For example, in some cases, the user experience platform is configured to generate the subsequent prompt based on a subsequent prompt template including natural language, where the subsequent prompt template is selected based on the identification of the data trend or the data anomaly, the initial response, or a combination thereof. In some cases, the subsequent prompt template is retrieved from the database.

In some cases, the subsequent prompt includes an instruction for the machine learning model to generate a response having content specified by the subsequent prompt (e.g., the response). In some cases, the subsequent prompt includes an instruction for the machine learning model to generate the response based on information included in the subsequent prompt, the initial response, the visual element corresponding to the initial response, or a combination thereof. For example, in some cases, the subsequent prompt includes the corpus of documents described with reference to FIG. 6.

In some cases, the subsequent prompt includes the query or the query embedding described with reference to FIG. 6. In some cases, the subsequent prompt includes the chart or the chart embedding described with reference to FIG. 6. In some cases, the subsequent prompt includes at least a portion of the initial response. In some cases, the user experience platform provides a chart generated based on the initial response to the multimodal encoder, the multimodal encoder encodes the chart generated based on the initial response to obtain a generated chart embedding, and the subsequent prompt includes the generated chart embedding. In some cases, the multimodal encoder encodes the subsequent prompt to obtain a subsequent prompt embedding. In some cases, the subsequent prompt includes content provider data for the content provider (such as a content provider identifier). In some cases, the subsequent prompt includes user data for one or more users associated with the content provider.

According to some aspects, the machine learning model generates the response based on the subsequent prompt. According to some aspects, the response comprises an “opportunity” as described herein. In some cases, the initial response and the subsequent prompt are omitted, and the machine learning model generates a response including an “insight”, an “opportunity”, or a combination thereof based on the prompt.

FIG. 8 shows an example of initial responses according to aspects of the present disclosure. The example shown includes user interface 800, portion of first initial response 805, portion of second initial response 810, portion of third initial response 815, first visual element 820, second visual element 825, and third visual element 830. User interface 800 is an example of, or includes aspects of, the corresponding element described with reference to FIGS. 2, 4, and 9-13.

In the example shown in FIG. 8, user interface 800 displays portion of first initial response 805, portion of second initial response 810, and portion of third initial response 815 of respective first, second, and third initial responses generated by a machine learning model (such as the machine learning model described with reference to FIGS. 2 and 4) in response to a detection of respectively corresponding data trends and/or data anomalies. For example, the first initial response is an “insight” as described herein corresponding to a detection from internal and external data sources of an emerging trend of solo traveling, and portion of first initial response 805 includes a natural language statement describing an analysis of the emerging trend of solo traveling.

As shown in FIG. 8, each of portion of first initial response 805, portion of second initial response 810, and portion of third initial response 815 is displayed within first visual element 820 displayed by user interface 800, and portion of first initial response 805 is displayed within second visual element 825 together with third visual element 830. In some cases, one or more of first visual element 820, second visual element 825, and third visual element 830 are generated based on information provided by one or more of the first initial response, the second initial response, or the third initial response, or is generated according to a visual element generation function of a user experience platform (such as the user experience platform described with reference to FIGS. 2 and 4), or a combination thereof.

In some cases, the placement of one or more of portion of first initial response 805, portion of second initial response 810, portion of third initial response 815, first visual element 820, second visual element 825, and third visual element 830 within user interface 800 is determined by information provided by one or more of the first initial response, the second initial response, or the third initial response, or is determined by the user experience platform, or a combination thereof.

As shown in FIG. 8, a link (e.g., a hyperlink) to “View more” is provided on user interface 800 adjacent to portion of first initial response 805. In some cases, in response to a content provider input to the link, the user interface displays information corresponding to first initial response 805 (including, for example, the portions of an initial response displayed in FIG. 9).

FIG. 9 shows an example of portions of an initial response according to aspects of the present disclosure. The example shown includes user interface 900, first portion of initial response 905, second portion of initial response 910, first visual element 915, second visual element 920, third visual element 925, fourth visual element 930, identification of data sources 935, and fact check visual element 940. User interface 900 is an example of, or includes aspects of, the corresponding element described with reference to FIGS. 2, 4, 8, and 10-13.

Referring to FIG. 9, according to some aspects, a user interface displays information corresponding to an initial response generated by a machine learning model (such as the machine learning model described with reference to FIGS. 2 and 4). FIG. 9 shows an example in which first portion of initial response 905, second portion of initial response 910, first visual element 915, second visual element 920, third visual element 925, fourth visual element 930, identification of data sources 935, and fact check visual element 940 are displayed by user interface 900.

In the example of FIG. 9, the initial response is an insight, and each of first portion of initial response 905 and second portion of initial response 910 includes natural language corresponding to a detection from internal and external data sources of an emerging trend of solo traveling. In particular, first portion of initial response 905 includes a natural language statement describing an analysis of the emerging trend of solo traveling, and second portion of initial response 910 includes a natural language statement of a numerical analysis of the emerging trend and an identification of a sub-trend of solo travelers engaging in group activities at their destinations. As shown, second portion of initial response 910 also includes a suggestion in natural language of an action a content provider might wish to take based on the identified sub-trend.

In the example of FIG. 9, first visual element 915, second visual element 920, third visual element 925, and fourth visual element 930 are displayed alongside first portion of initial response 905 and second portion of initial response 910. According to some aspects, one or more of first visual element 915, second visual element 920, third visual element 925, and fourth visual element 930 are generated and/or retrieved by a user experience platform (such as the user experience platform described with reference to FIGS. 2 and 4) based on the initial response. For example, in some cases, the initial response includes code or instructions to generate and/or retrieve one or more of first visual element 915, second visual element 920, third visual element 925, and fourth visual element 930, and the user experience platform generates and/or retrieves one or more of first visual element 915, second visual element 920, third visual element 925, and fourth visual element 930 based on the code or instructions. As shown, one or more of second visual element 920, third visual element 925, and fourth visual element 930 comprise a chart as described herein.

In the example of FIG. 9, identification of data sources 935 comprises one or more sources of data used by the machine learning model to generate the initial response. In the example of FIG. 9, fact check visual element 940 provides a user interface element for a content provider to obtain additional information corresponding to the initial response. For example, in some cases, in response to a content provider input provided to fact check visual element 940, user interface 900 displays a link to the one or more sources of data, or displays information relating to or included in the one or more sources of data

In some cases, text elements included in one or more of second visual element 920, third visual element 925, and fourth visual element 930 comprise a portion of the initial response. According to some aspects, one or more of first portion of initial response 905, second portion of initial response 910, first visual element 915, second visual element 920, third visual element 925, fourth visual element 930, and identification of data sources 935 is displayed according to a visual format determined by the user experience platform. According to some aspects, the user experience platform determines the format based on formatting information included in the initial response.

FIG. 10 shows an example of a user interface message element according to aspects of the present disclosure. The example shown includes user interface 1000 and user interface message element 1005. User interface 1000 is an example of, or includes aspects of, the corresponding element described with reference to FIGS. 2, 4, 8, 9, and 11-13.

According to some aspects, user interface 1000 displays user interface message element 1005 when a content provider interacts with an element of user interface 1000 corresponding to an initial response (such as elements of the user interface described with reference to FIG. 9). In the example of FIG. 10, user interface message element 1005 is a pop-up window displayed above other elements of user interface 1000. In the example of FIG. 10, user interface message element 1005 displays a content provider message (e.g., “What would you like to do?”). In some cases, a content provider (such as the content provider described with reference to FIGS. 1 and 5) provides an input to user interface message element 1005. In response to the input, the user interface message element 1005 or a different element of user interface 1000 is allowed to receive a query from the content provider (such as the query described with reference to FIG. 11).

FIG. 11 shows an example of a response according to aspects of the present disclosure. The example shown includes user interface 1100, query 1105, first portion of response 1110, second portion of response 1115, third portion of response 1120, fourth portion of response 1125, first visual element 1130, second visual element 1135, and third visual element 1140. User interface 1100 is an example of, or includes aspects of, the corresponding element described with reference to FIGS. 2, 4, 8-10, and 12-13. Query 1105 is an example of, or includes aspects of, the corresponding element described with reference to FIG. 4.

As shown in FIG. 11, user interface 1100 displays query 1105 in first visual element 1130. In the example of FIG. 11, query 1105 comprises the natural language text “I want to leverage this emerging trend. What are the options?”. In some cases, a content provider (such as the content provider described with reference to FIGS. 1 and 5) provides query 1105 to first visual element 1130 in response to a user interface message element (such as the user interface message element described with reference to FIG. 10). In some cases, a machine language model generates a response (including, e.g., first portion of response 1110, second portion of response 1115, third portion of response 1120, and fourth portion of response 1125) in response to query 1105 as described with reference to FIGS. 6 and 7.

As shown in FIG. 11, the response is an opportunity as described herein. For example, first portion of response 1110 includes natural language text summarizing suggested actions for a content provider based on query 1105, while second portion of response 1115, third portion of response 1120, and fourth portion of response 1125 include natural language text describing respectively different suggested actions for the content provider to take in response to the query. Each of first portion of response 1110, second portion of response 1115, third portion of response 1120, and fourth portion of response 1125 are displayed within second visual element 1135. In an example, second portion of response 1115 is displayed adjacent to third visual element 1140. In some cases, a user experience platform (such as the user experience platform described with reference to FIGS. 1 and 4) generates and/or retrieves a visual element (such as third visual element 1140) based on the response.

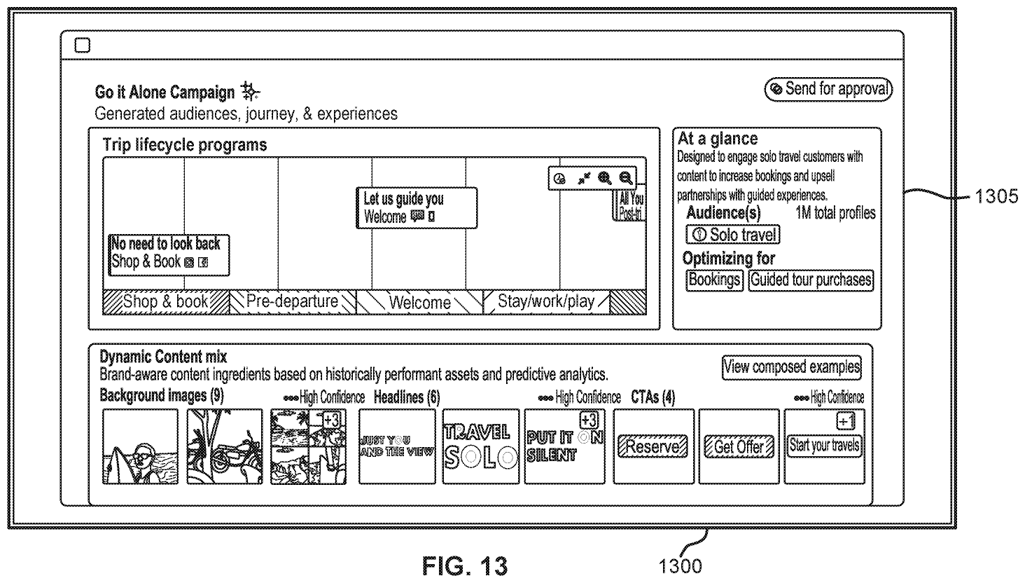

According to some aspects, the content provider provides an input to a visual element associated with one or more of second portion of response 1115, third portion of response 1120, and fourth portion of response 1125. In some cases, in response to the content provider input, the user interface displays an additional visual element (such as the additional visual element described with reference to FIG. 13).

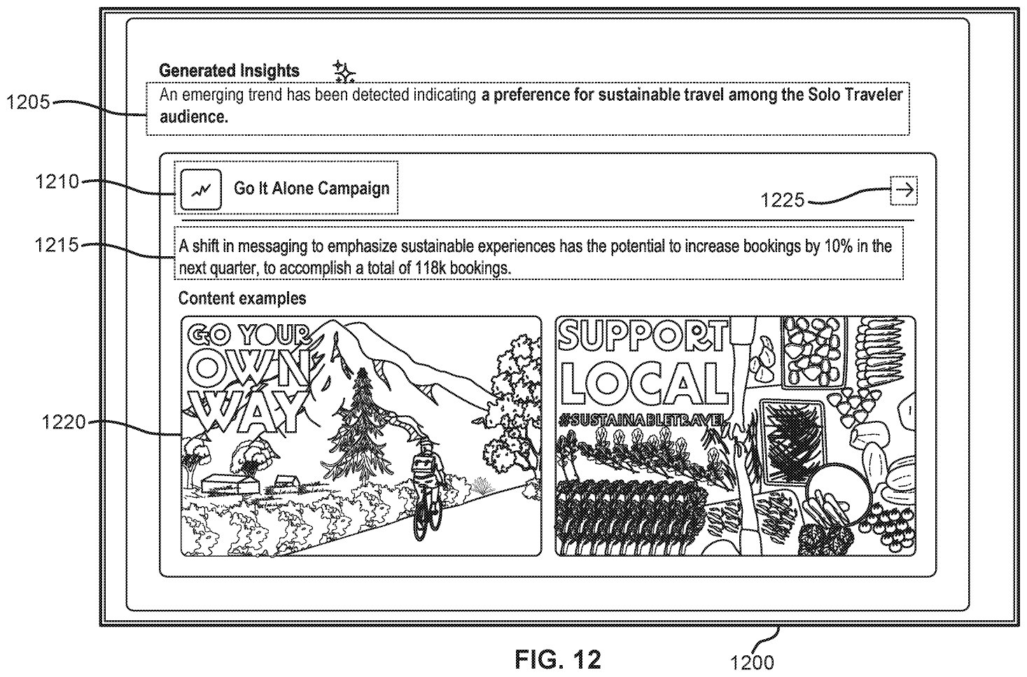

FIG. 12 shows an example of an insight generated based on a campaign according to aspects of the present disclosure. The example shown includes user interface 1200, description of data trend 1205, campaign label 1210, portion of response 1215, visual element 1220, and preview element 1225. User interface 1200 is an example of, or includes aspects of, the corresponding element described with reference to FIGS. 2, 4, 8-11, and 13.

Referring to FIG. 12, according to some aspects, a data processing apparatus (such as the data processing apparatus described with reference to FIGS. 1-2) detects a data trend or anomaly corresponding to a content distribution campaign for a content provider (such as the content provider described with reference to FIG. 1) and generates an insight based on the detected data trend or anomaly.

In the example of FIG. 12, user interface 1200 displays description of data trend 1205 corresponding to a content provider content distribution campaign targeting a Solo

Traveler user segment, labeled using campaign label 1210 (e.g., “Go It Alone Campaign”). As shown in FIG. 12, description of data trend 1205 describes an emerging trend of a preference for sustainable travel among the Solo Traveler audience.

In some cases, a machine learning model (such as the machine learning model described with reference to FIGS. 2 and 4) generates a response (e.g., an insight) as described herein in response to the detection of the data trend. User interface 1200 displays portion of response 1215. In some cases, a user experience platform (such as the user experience platform described with reference to FIGS. 2 and 4) generates and/or retrieves visual element 1220 based on the response.

According to some aspects, the content provider interacts with preview element 1225 to view a suggest modification to the content distribution campaign based on the detected trend. Accordingly, in some cases, insights and opportunities are continuously identified, and the accuracy and relevancy of a response generated by the machine learning model are optimized over time through feedback loops.

FIG. 13 shows an example of an additional visual element according to aspects of the present disclosure. The example shown includes user interface 1300 and additional visual element 1305. User interface 1300 is an example of, or includes aspects of, the corresponding element described with reference to FIGS. 2, 4, and 8-12.

Referring to FIG. 13, user interface 1300 displays additional visual element 1305 in response to a content provider input provided to a visual element of user interface 1300 corresponding to a response (such as a visual element described with reference to FIG. 11). In the example of FIG. 13, additional visual element 1305 comprises a display of a combination of text elements corresponding to information related to a campaign and generated and/or retrieved by one or more of a machine learning model (such as the machine learning model described with reference to FIGS. 2 and 4) and a user experience platform (such as the user experience platform described with reference to FIGS. 2 and 4). In some cases, at least a portion of the information related to the campaign is generated by the machine learning model based on the content provider input provided to the visual element of user interface 1300 corresponding to the response.

Accordingly, in some cases, each of FIGS. 8-13 shows a user interface that integrates capabilities of the user experience platform with language capabilities of the machine learning model to provide a multi-modal conversation interface that displays text, visuals, charts, and other formats in a manner contextually suited for a content provider.

### Training

A method for data processing is described with reference to FIG. 14. One or more aspects of the method include obtaining training data including a corpus of documents from a domain, chart data from the domain, a training query, and a ground-truth response to the training query and training a machine learning model to answer domain-specific questions in the domain using the training data.

Some examples of the method further include training the machine learning model to answer the domain specific questions based on a query embedding. Some examples of the method further include training the machine learning model to answer the domain-specific questions based on a chart embedding. Some examples of the method further include training the machine learning model to generate a chart using the training data.

FIG. 14 shows an example of a method 1400 for training a machine learning model according to aspects of the present disclosure. In some examples, these operations are performed by a system including a processor executing a set of codes to control functional elements of an apparatus. Additionally or alternatively, certain processes are performed using special-purpose hardware. Generally, these operations are performed according to the methods and processes described in accordance with aspects of the present disclosure. In some cases, the operations described herein are composed of various substeps, or are performed in conjunction with other operations.

At operation 1405, the system obtains training data including a corpus of documents from a domain, chart data from the domain, a training query, and a ground-truth response to the training query. In some cases, the operations of this step refer to, or are performed by, a training component as described with reference to FIG. 2.

For example, in some cases, the training component retrieves at least a portion of the training data from a database (such as the database described with reference to FIG. 1) or from another data source (such as the Internet). In some cases, the chart data comprises a chart. In some cases, the chart data comprises data associated with a chart. In some cases, the training query comprises natural language. In some cases, the ground-truth response to the training query comprises an intended output of a machine learning model (such as the machine learning model described with reference to FIGS. 2 and 5) comprising one or more of natural language and computer code that the machine learning model would be expected to output in response to receiving the corpus of documents, the chart data, and the training query as input.

According to some aspects, the corpus of documents comprises external and/or internal data sources. In some cases, the data sources are inclusive of at least one of a foundational enterprise/content distribution focus and a unique content provider-specific foundation.

Examples of data having a foundational enterprise/content distribution focus include publicly available competitor information and announcements, market research reports, brand awareness and perception data, company and industry data, demographic data, seasonal data, macroeconomic data, microeconomic data, and data relating to world events.

Examples of data having a content provider-specific foundation include user and segmentation data, content affinity data based on historical responses to content distribution campaigns, user journey preferences (such as frequency, channels, and content preferences) based on historical performance of content distribution campaigns, share partner or purchased data, historical content distribution campaign details and performance data, brand guidelines and historical content experiences, previous experiments and results, and user research, such as market research and churn analysis.

At operation 1410, the system trains a machine learning model to answer domain-specific questions in the domain using the training data. In some cases, the operations of this step refer to, or are performed by, a training component as described with reference to FIG. 2.

For example, in some cases, the training component provides a combination of the corpus of documents, the chart data, and the training query to the machine learning model, or one or more respective embeddings of the corpus of documents, the chart data, and the training query to the machine learning model as input. The machine learning model generates a response based on the input. In some cases, the training component compares the response to the ground-truth response to the training query to determine a loss function.

The term “loss function” refers to a function that impacts how a machine learning model is trained in a supervised learning model. For example, during each training iteration, the output of the machine learning model is compared to the known annotation information in the training data. The loss function provides a value (a “loss”) for how close the predicted annotation data is to the actual annotation data. After computing the loss, the parameters of the model are updated accordingly and a new set of predictions are made during the next iteration.

Supervised learning is one of three basic machine learning paradigms, alongside unsupervised learning and reinforcement learning. Supervised learning is a machine learning technique based on learning a function that maps an input to an output based on example input-output pairs. Supervised learning generates a function for predicting labeled data based on labeled training data consisting of a set of training examples. In some cases, each example is a pair consisting of an input object (typically a vector) and a desired output value (i.e., a single value, or an output vector). In some cases, a supervised learning algorithm analyzes the training data and produces the inferred function, which is used for mapping new examples. In some cases, the learning results in a function that correctly determines the class labels for unseen instances. In other words, the learning algorithm generalizes from the training data to unseen examples.

In some cases, the training component trains the machine learning model by updating the machine learning parameters of the machine learning model according to the loss function. According to some aspects, the training component fine-tunes the machine learning parameters of the machine learning model based on the corpus of documents.

In some cases, the training component trains the machine learning model to answer the domain specific questions based on a query embedding. In some cases, the training component trains the machine learning model to answer the domain-specific questions based on a chart embedding.

According to some aspects, the training component identifies a historical response (such as an insight or an opportunity described herein) generated by the machine learning model. In some cases, the historical response is stored in a database (such as the database described with reference to FIG. 1). In some cases, the training component includes the historical response in the training data. In some cases, the training component provides the historical response, or an embedding of the historical response, to the machine learning model. In some cases, the machine learning model generates the response based on the historical response. Accordingly, in some cases, insights and opportunities are continuously identified, and the accuracy and relevancy of a response generated by the machine learning model are optimized over time through feedback loops.

The description and drawings described herein represent example configurations and do not represent all the implementations within the scope of the claims. For example, the operations and steps can be rearranged, combined, or otherwise modified. Also, structures and devices can be represented in the form of block diagrams to represent the relationship between components and avoid obscuring the described concepts. Similar components or features can have the same name but can have different reference numbers corresponding to different figures.

Some modifications to the disclosure are readily apparent to those skilled in the art, and the principles defined herein can be applied to other variations without departing from the scope of the disclosure. Thus, the disclosure is not limited to the examples and designs described herein, but is to be accorded the broadest scope consistent with the principles and novel features disclosed herein.

In some embodiments, the described methods are implemented or performed by devices that include a general-purpose processor, a digital signal processor (DSP), an application specific integrated circuit (ASIC), a field programmable gate array (FPGA) or other programmable logic device, discrete gate or transistor logic, discrete hardware components, or any combination thereof. In some embodiments, a general-purpose processor is a microprocessor, a conventional processor, controller, microcontroller, or state machine. In some embodiments, a processor is implemented as a combination of computing devices (e.g., a combination of a DSP and a microprocessor, multiple microprocessors, one or more microprocessors in conjunction with a DSP core, or any other such configuration). Thus, in some embodiments, the functions described herein are implemented in hardware or software and are executed by a processor, firmware, or any combination thereof. In some embodiments, if implemented in software executed by a processor, the functions are stored in the form of instructions or code on a computer-readable medium.

Computer-readable media includes both non-transitory computer storage media and communication media including any medium that facilitates transfer of code or data. In some embodiments, a non-transitory storage medium is any available medium that can be accessed by a computer. For example, in some cases, non-transitory computer-readable media comprise random access memory (RAM), read-only memory (ROM), electrically erasable programmable read-only memory (EEPROM), compact disk (CD) or other optical disk storage, magnetic disk storage, or any other non-transitory medium for carrying or storing data or code.

Also, in some embodiments, connecting components are properly termed computer-readable media. For example, if code or data is transmitted from a website, server, or other remote source using a coaxial cable, fiber optic cable, twisted pair, digital subscriber line (DSL), or wireless technology such as infrared, radio, or microwave signals, then the coaxial cable, fiber optic cable, twisted pair, DSL, or wireless technology are included in the definition of medium. Combinations of media are also included within the scope of computer-readable media.

In this disclosure and the following claims, the word “or” indicates an inclusive list such that, for example, the list of X, Y, or Z means X or Y or Z or XY or XZ or YZ or XYZ. Also the phrase “based on” is not used to represent a closed set of conditions. For example, a step that is described as “based on condition A” can be based on both condition A and condition B. In other words, the phrase “based on” shall be construed to mean “based at least in part on.” Also, the words “a” or “an” indicate “at least one.”

What is claimed is:

1. A method for data processing, comprising:
receiving, from a content provider via a user interface, a query about a chart that includes information related to a domain;
generating, using a machine learning model, a response to the query based on the chart and a corpus of documents in the domain, wherein the response includes information from the corpus of documents; and
providing, via the user interface, at least a portion of the response to the content provider.

2. The method of claim 1, wherein:
the machine learning model is trained to answer questions in the domain using the corpus of documents as training data.

3. The method of claim 1, further comprising:
encoding, using a multimodal encoder, the query to obtain a query embedding, wherein the response is generated based on the query embedding.

4. The method of claim 1, further comprising:
encoding the chart using a multimodal encoder to obtain a chart embedding, wherein the response is generated based on the chart embedding.

5. The method of claim 1, further comprising:
generating, using a user experience platform, a visual element corresponding to the response; and
displaying, via the user interface, the visual element to the content provider in response to the query.

6. The method of claim 1, further comprising:
identifying, using a user experience platform, chart data associated with the chart, wherein the response is based on the chart data.

7. The method of claim 1, further comprising:
identifying, using a user experience platform, a data trend in the domain;
generating, using the user experience platform, a prompt based on the data trend, wherein the prompt comprises information included in the corpus of documents;
generating, using the machine learning model, an initial response based on the prompt; and
displaying, via the user interface, at least a portion of the initial response.

8. The method of claim 7, further comprising:
generating, using the user experience platform, a subsequent prompt based on the query and the initial response; and
generating the response based on the subsequent prompt.

9. The method of claim 8, wherein:
the subsequent prompt further comprises one or more of content provider data for the content provider and user data for one or more users associated with the content provider.

10. The method of claim 7, wherein:
the portion of the initial response indicates a source of information from the corpus of documents.

11. The method of claim 7, wherein:
the portion of the initial response comprises a natural language response describing the data trend.

12. The method of claim 1, wherein:
the portion of the response suggests one or more content provider actions.

13. A method for data processing, comprising:
obtaining, using a training component, training data including a corpus of documents from a domain, chart data from the domain, a training query, and a ground-truth response to the training query; and
training, using the training component, a machine learning model to answer domain-specific questions in the domain using the training data.

14. The method of claim 13, further comprising:
training, using the training component, the machine learning model to answer the domain-specific questions based on a query embedding.

15. The method of claim 13, further comprising:
training, using the training component, the machine learning model to answer the domain-specific questions based on a chart embedding.

16. The method of claim 13, further comprising:
training, using the training component, the machine learning model to generate a chart using the training data.

17. An apparatus for data processing, comprising:
at least one processor;
at least one memory storing instructions executable by the at least one processor;
a user interface configured to receive a query about a chart that includes information related to a domain; and
a machine learning model including machine learning parameters stored in the at least one memory and trained to generate a response to the query based on the chart and a corpus of documents in the domain, wherein the response includes information from the corpus of documents.

18. The apparatus of claim 17, wherein:
the machine learning model comprises a transformer.

19. The apparatus of claim 17, further comprising:
a multimodal encoder including multimodal encoder parameters stored in the at least one memory and trained to encode the chart to obtain a chart embedding.

20. The apparatus of claim 17, further comprising:
a user experience platform configured to generate a prompt for the machine learning model.
